(19) United States
(12) Patent Application Publication
(10) Pub. No.: US 2026/0148368 A1
(43) Pub. Date: May 28, 2026

(54) METHOD AND SYSTEM FOR DETECTING DEFECTS IN A PHOTOLITHOGRAPHY MASK, FOR TRAINING A CORRESPONDING MACHINE LEARNING MODEL AND FOR GENERATING CORRESPONDING TRAINING DATA

(71) Applicant: Carl Zeiss SMT GmbH, Oberkochen (DE)

(72) Inventors: Ecaterina Bodnariuc, Berlin (DE); Gilles Tabbone, Lournand (FR); Bjoern Froehlich, Jena (DE); Mario Kanka, Jena (DE); Stephan Ratzsch, Jena (DE); Bjoern Brauer, Magstadt (DE); Klaus Gwosch, Aalen (DE); Renzo Capelli, Heidenheim (DE); Alexander Freytag, Erfurt (DE); Xuan Truong Nguyen, Berlin (DE)

(21) Appl. No.: 19/397,076

(22) Filed: Nov. 21, 2025

(30) Foreign Application Priority Data
Nov. 25, 2024 (DE) 102024134609.4

(51) Int. Cl. G06T 7/00; G06N 20/00; G06T 5/70

(52) U.S. Cl. CPC G06T 7/0008; G06N 20/00; G06T 5/70; G06T 7/001; G06T 2207/20081; G06T 2207/20182; G06T 2207/30108

(57) ABSTRACT

The invention relates to a method for detecting defects in a photolithography mask, the method comprising the following steps: acquiring an aerial image of the photolithography mask using an optical system; denoising the acquired aerial image using a machine learning model that is trained to reduce a noise level of an aerial image; and detecting defects in the photolithography mask using the denoised aerial image. The invention also relates to a method for training a corresponding machine learning model, to a method for generating training data for a corresponding machine learning model and to a system for detecting defects in photolithography masks.

### CROSS-REFERENCE TO RELATED APPLICATION

This application claims benefit of German patent application 10 2024 134 609.4, filed on Nov. 25, 2024, which is hereby incorporated by reference in its entirety.

### TECHNICAL FIELD

The invention relates to methods and systems for detecting defects in a photolithography mask obtained by an optical system, for training a corresponding machine learning model and for generating corresponding training data. The methods and systems can be utilized, for example, for quality control and process monitoring for photolithography masks.

### BACKGROUND

Photolithography is a process used to produce patterns on a substrate. The patterns to be printed on the surface of the substrate are generated by computer-aided-design (CAD). From the design, for each layer a photolithography mask is generated, which contains a magnified image of the computer-generated pattern to be etched into the substrate. The photolithography mask can be further adapted, e.g., by use of optical proximity correction techniques. During the printing process an illuminated image projected from the photolithography mask is focused onto a photoresist thin film formed on the substrate.

Due to the growing integration density in the semiconductor industry, photolithography masks have to image increasingly smaller structures onto wafers. The aspect ratio and the number of layers of integrated circuits constantly increases and the structures are growing into 3^{rd} (vertical) dimension. In contrast, the feature size is becoming smaller. The minimum feature size or critical dimension is below 10 nm, for example, 7 nm or 5 nm, and is approaching feature sizes below 3 nm in near future.

On account of the tiny structure sizes of the pattern elements of photolithographic masks or templates, it is not possible to exclude errors during mask or template production. Hence, in semiconductor process control, photolithography mask inspection, review, and metrology play a crucial role to monitor defects. Defects detected during quality assurance processes can be used for root cause analysis, for example, to modify or repair the photolithography mask. The defects can also serve as feedback to improve the process parameters of the mask manufacturing process in mask shops. Mask inspection is, thus, a critical process step for maintaining high yield in production pipelines in semiconductor manufacturing.

For mask inspection, aerial images can be used that indicate the radiation intensity distribution of a photolithography system in a wafer plane for a given photolithography mask. The aerial image, thus, simulates the structures on the surface of a wafer when printing the wafer using the photolithography mask in the photolithography system. The photolithography mask can, thus, be inspected without having to print wafers.

The requirements concerning speed and throughput in mask shops and semiconductor manufacturing plants are, however, very demanding, since the entire surface of a photolithography mask must be inspected for defects within a restricted time window. Therefore, a compromise must be found between different mask inspection parameters such as throughput, imaging speed, spatial resolution, illumination source and exposure time.

Aerial images acquired at high speed are extremely noisy due to low light intensity and short exposure times. An important and often dominant source of noise in the aerial images is shot noise, which is due to a low photon count used to expose a surface area on the photolithography mask. Other sources of noise include noise originating from camera sensors such as stray light noise, dark current noise, read out noise from digital sensors, fixed pattern noise, jitter noise, and noise induced by digital signal processing steps such as quantization noise, clipping noise, or data transmission noise. The inevitably high noise level in aerial images degrades the reliability and accuracy of defect detection methods. In addition, the aerial image capturing process is stochastic leading to a high variability of aerial images and, thus, a low reliability and reproducibility of defect detection results.

U.S. Pat. No. 11,170,475 B2 discloses a method for obtaining improved defect detection results by denoising images of wafers acquired by a scanning electron microscope (SEM). However, SEM images of wafers exhibit very different image characteristics such as a different resolution, noise source and noise statistics compared to aerial images of photolithography masks that mainly contain shot noise. The unsupervised method for SEM image denoising heavily relies on the assumption that the noise in the SEM image is independent and identically distributed (iid) in order to generate a target image suitable for the training of the model. An identical noise distribution implies that the noise is invariant to signal intensity. This is not the case for shot noise in aerial images, since it depends on photon counts and, thus, on the pixel intensity. Independent noise implies pixel-wise uncorrelated noise, which is not the case for many sources of noise, e.g., jitter and speckle noise is correlated. In addition, the independence condition may be easily violated if other processing steps are applied to the raw aerial image, for example, filtering or local averaging. Furthermore, SEM images can exhibit very high noise levels up to 50%, whereas shot noise levels are usually very low around 2 to 5%. The method presented in this article is, thus, not well suitable for denoising aerial images.

Therefore, it is an aspect of this invention to improve the denoising of aerial images. It is another aspect of this invention to increase the quality and reproducibility of defect detection methods in aerial images of photolithography masks.

The aspects are achieved by the invention specified in the independent claims. Advantageous embodiments and further developments of the invention are specified in the dependent claims.

### SUMMARY

Embodiments of the invention concern methods and systems for improving the image quality, in particular the noise level, of an aerial image of a photolithography mask.

A first embodiment involves a method for detecting defects in a photolithography mask, the method comprising the following steps: acquiring an aerial image of the photolithography mask using an optical system; denoising the acquired aerial image using a machine learning model that is trained to reduce a noise level of an aerial image; and detecting defects in the photolithography mask using the denoised aerial image.

By reducing a noise level of the acquired aerial image before defect detection, nuisances are removed from the aerial image such that the accuracy of the detected defects is improved. Since a machine learning model is used for reducing the noise level of the aerial image, the quality of the noise reduced aerial image is improved, since the machine learning model directly learns from training data to minimize the loss function. Furthermore, the effort for the user is reduced, as the machine learning model learns automatically without having to define rules or algorithms. In addition, the reproducibility of defect detections is improved in photolithography mask inspection due to the reduced noise levels of the aerial images. The method also works for various noise levels without having to make specific assumptions about noise statistics.

The term “defect” refers to a localized deviation of a photolithography mask from an a priori defined norm of the photolithography mask. The norm of the photolithography mask can be defined by one or more corresponding reference objects or reference datasets, e.g., by design datasets, simulated datasets or acquired defect-free datasets. For instance, a defect of a photolithography mask can result in malfunctioning of a printed wafer and, thus, of a complete associated semiconductor device. Depending on the number and/or nature of the detected defects on the mask, photolithography masks can, for example, be repaired or discarded.

An “aerial image” indicates the radiation intensity distribution of a photolithography system in a wafer plane for a given photolithography mask. It is the projected image of the photolithography mask in air at the air/resist interface. An aerial image refers to the image that is formed by the projection of light, e.g., of EUV or DUV wavelength, through a photolithography mask onto an imaging sensor, e.g., charge coupled device (CCD) or complementary metal oxide semiconductor (CMOS) arrays. The aerial image, thus, simulates the structures on the surface of a wafer when printing the wafer using the photolithography mask in a photolithography system. As the optical fidelity of the aerial image is unperturbed by the resist processing steps, it is possible to analyze the image formation for optical errors (treating the photolithography mask as an optical component). Since the projected image incorporates the real three dimensional geometric and material properties of the photomask, the generated aerial image represents the summation of influences on a printed wafer and is particularly suitable for defect detection or metrology.

An aerial image can be generated by applying an aerial image measurement system or metrology system to a photolithography mask. An aerial image can be simulated using a design of a photolithography mask and an aerial image simulation method.

An aerial image can refer to the aerial image of a complete photolithography mask, or it can refer to the aerial image of a section of the photolithography mask. A design can refer to the design of a complete photolithography mask, or it can refer to the design of a section of the photolithography mask.

An “optical system” refers to a system that uses light to inspect a photolithography mask. It illuminates the photolithography mask with light from an illumination source and projects the reflected or transmitted light from the photolithography mask surface to a camera sensor array. Optical systems comprise, for example, inspection systems, optical mask qualification systems and metrology systems.

An inspection system refers to an optical system used to detect defects in a photolithography mask by acquiring and analyzing aerial images of the photolithography mask or one or more sections thereof. In particular, inspection systems comprise actinic photomask inspection systems.

An optical mask qualification system refers to a system that is used to acquire an aerial image of a portion of a photolithography mask, thereby emulating settings of a photolithography system, e.g., illumination and imaging parameters. The acquired aerial image is of a higher quality than an aerial image acquired by an inspection system, e.g., of a reduced noise level. The portions of the photolithography mask can comprise potential defect locations detected using an inspection system. The acquired aerial image can be used to examine the effect of a potential defect on a printed wafer, to verify that photolithography masks are defect-free, to review whether a repair attempt has been successful or for critical dimension estimation.

A metrology system refers to a system that is used to take measurements of structures in a photolithography mask by acquiring and analyzing an aerial image of the photolithography mask.

Parameters describing an optical system comprise, for example,
illumination parameters describing the illumination setting of the photolithography system, comprising the distribution and intensities of different illumination angles, e.g., an annular illumination setting, a dipole illumination setting, a quasar illumination setting, etc.,
imaging parameters such as the numerical aperture of the photolithography system and the magnification of the photolithography system, obscurations, aberrations, apodizations or distortions,
design parameters such as parameters describing the material of the photolithography mask, e.g., layer thicknesses, refractive indices of different layers, etc.

The photolithography mask may have an aspect ratio of between 1:1 and 1:4, preferably between 1:1 and 1:2, most preferably of 1:1 or 1:2. The photolithography mask may have a nearly rectangular shape. The photolithography mask may be preferably 12.7 cm (5 inches) to 17.8 cm (7 inches) long and wide, most preferably 15.2 cm (6 inches) long and wide. Alternatively, the photolithography mask may be 12.7 cm (5 inches) to 17.8 cm (7 inches) long and 25.4 cm (10 inches) to 35.6 cm (14 inches) wide, preferably 15.2 cm (6 inches) long and 30.5 cm (12 inches) wide.

In order to analyze large amounts of data obtained from extensive amounts of measurements, machine learning methods can be used. Machine learning is a field of artificial intelligence. Machine learning methods generally build a parametric machine learning model based on training data consisting of a large number of samples. After training, the method is able to generalize the knowledge gained from the training data to new previously unencountered samples, thereby making predictions for new data. There are many machine learning methods, e.g., linear regression, k-means, support vector machines, decision trees, random forests, neural networks or deep learning approaches. Machine learning models are parametric models whose parameters are optimized during training. The machine learning model and the learned parameters can be applied to make predictions for new input data. Machine learning models comprise, for example, neural networks, support vector machines, decision trees, random forests, subspaces, cluster sets, etc.

Deep learning is a class of machine learning that uses artificial neural networks with numerous hidden layers between the input layer and the output layer. Due to this complex internal structure the networks are able to progressively extract higher-level features from the raw input data. Each level learns to transform its input data into a slightly more abstract and composite representation, thus deriving low and high level knowledge from the training data. The hidden layers can have differing sizes and tasks such as convolutional or pooling layers.

Machine learning models are trained using training data, i.e., examples, and, thus, independently derive their knowledge from the training data instead of requiring a user to define rules for defect detection. In this way, optimal results with respect to the minimized loss function can be obtained automatically in a data-driven way. Thus, the use of machine learning methods increases the recall and precision of the denoising method and reduces the required user effort.

The term “noise” refers to random variations in the aerial image signal. Noise includes but is not limited to shot noise that is due to low illumination at short exposure times, sensor noise such as dark current noise and stray light noise, jitter noise that refers to a signal's timing from its nominal value leading to variations in phase, period, width, or duty cycle, and noise due to signal processing such as clipping, quantization or data transfer.

A “noise level” refers to the standard deviation of the noise in an aerial image.

A “signal-to-noise ratio” (SNR) of an aerial image refers to the ratio of the power of the image signal and the power of noise in the aerial image. It measures the quality of the aerial image.

A “denoised aerial image” refers to an aerial image whose noise level is reduced with respect to its original noise level, or to a noise-free aerial image.

The aerial image of the photolithography mask can be acquired by the optical system using light of an actinic wavelength. In this way, the aerial image can be of a higher contrast and resolution leading to a higher defect prediction accuracy. Furthermore, phase defects in multilayers of extreme ultraviolet (EUV) photolithography masks can be detected with higher accuracy.

According to an example, a design of the photolithography mask is provided as an additional input to the machine learning model for reducing a noise level of an aerial image. The design can help to resolve ambiguities in the structures in the aerial image during denoising and, thus, improves the prediction accuracy of the machine learning model for reducing a noise level of an aerial image.

A design of a photolithography mask refers to a representation of properties of the photolithography mask or a section thereof.

In an example, the trained machine learning model for reducing a noise level of an aerial image comprises a deep learning model with an encoder-decoder architecture, e.g., a convolutional neural network (CNN), a U-Net, a variational autoencoder or a generative adversarial neural network (GAN). Such machine learning models map the input to a lower-dimensional space and reconstruct the input again from this space. Due to the lower dimensionality, only the most relevant information is preserved in the subspace, and, thus, noise is effectively reduced.

According to an aspect of the invention, the trained machine learning model for reducing a noise level of an aerial image comprises a diffusion model that is trained to decrease a noise level in the aerial image of the photolithography mask in multiple diffusion steps. A diffusion model is advantageous, as it does not necessarily require aerial image for training but can be trained on any other type of noisy images. In this way, the effort for training the machine learning model for reducing a noise level of an aerial image can be reduced.

According to a second embodiment of the invention, a method for detecting defects in an aerial image of a photolithography mask comprises: acquiring an aerial image of the photolithography mask using an optical system; obtaining a reference image of the photolithography mask; obtaining a denoised aerial image and a denoised reference image by reducing at least one of the noise level of the aerial image and the noise level of the reference image such that the noise levels approximately match; and detecting defects in the photolithography mask using the denoised aerial image and the denoised reference image.

The method for detecting defects in an aerial image according to a third embodiment of the invention further comprises verifying the reduction of the noise level of the denoised aerial image using an image quality criterion. The image quality criterion can comprise comparing an estimated noise level and/or a measurement of preserved structure in the denoised aerial image and in the acquired aerial image. By verifying the reduction of the noise level, a continuous quality control of the noise reduction and defect detection method is possible.

According to an aspect of the invention, defects are detected in the denoised aerial image by comparing the denoised aerial image to a reference image, and the image quality criterion comprises comparing the denoised aerial image and the acquired aerial image to an estimated mean image of the acquired aerial image and the reference image. The estimated mean image contains a lower noise level due to the averaging of two noisy aerial images and, thus, can serve as a baseline for measuring image quality. In this way, quality control is made possible.

The method for detecting defects in an aerial image can further comprise, upon not fulfilling the image quality criterion, using the acquired aerial image for detecting defects. In this way, in case of a presumably low quality of the denoised aerial image, the original acquired aerial image is used for defect detection to prevent low-quality defect detections.

The method for detecting defects in an aerial image can further comprise, repeating the steps of the method multiple times and, upon not fulfilling the image quality criterion for a number of acquired aerial images, initiating a re-training of the machine learning model for reducing a noise level of an aerial image. In this way, the machine learning model for reducing a noise level of an aerial image can be adapted to changing conditions, settings or environments to ensure high-quality defect detections.

Detecting defects can comprise comparing the denoised aerial image to a reference image. Detecting defects can comprise applying a template matching method to the denoised aerial image. Detecting defects can comprise applying a trained machine learning model for detecting defects to the denoised aerial image.

According to an example, the method for detecting defects in an aerial image can further comprise: providing a reference image for the acquired aerial image of the photolithography mask; denoising the reference image using the trained machine learning model for reducing a noise level of an aerial image, wherein detecting defects comprises comparing the denoised aerial image to the denoised reference image.

According to a preferred example, a trained joint machine learning model is used for reducing a noise level of an aerial image and for detecting defects in the denoised aerial image. Using a joint machine learning model improves the prediction accuracy for defect detections and simplifies the machine learning model.

According to a fourth embodiment of the invention, a computer implemented method for training a machine learning model for reducing a noise level of an aerial image of a photolithography mask obtained by an optical system comprises: providing training data comprising pairs of source aerial images and corresponding target aerial images configured for training the machine learning model for reducing a noise level of an aerial image of a photolithography mask obtained by an optical system; and training the machine learning model for reducing a noise level of an aerial image by minimizing a loss function using the training data.

In an example, the loss function comprises the distance between a predicted denoised source aerial image, obtained by presenting a source aerial image to the machine learning model for reducing a noise level of an aerial image, and the corresponding target aerial image.

According to a preferred example, the loss function comprises a distance measure in the frequency domain. In particular, the loss function comprises a distance measure of a target aerial image and a predicted denoised source aerial image in the frequency domain, wherein the predicted denoised source aerial image is obtained by presenting the corresponding source aerial image to the machine learning model for reducing a noise level of an aerial image. Due to the numerical aperture of the optical system, the image signal of the aerial image is band-limited, whereas the noise is spread over all frequency bands. Thus, noise, especially in case of low noise levels, is more pronounced in the frequency domain, which simplifies denoising and leads to more accurate predictions of the machine learning model for reducing a noise level of an aerial image. In addition, the training of the machine learning model is more robust with respect to tiny misalignments at subpixel level of source and target aerial images, since misalignments do not influence the spectrum magnitude of the images.

According to an aspect of the invention, the loss function comprises a regularization term that measures a phase shift between a source aerial image and a predicted denoised source aerial image, wherein the predicted denoised source aerial image is obtained by presenting the source aerial image to the machine learning model for reducing a noise level of an aerial image. The regularization term prevents misalignment between the denoised aerial image and the noisy aerial image and, thus, improves the quality of the denoised aerial image.

In an example, the machine learning model for reducing a noise level of an aerial image comprises a deep learning model with an encoder-decoder architecture, e.g., a convolutional neural network (CNN), a U-Net or a conditional generative adversarial neural network (GAN).

In an example, the source aerial image of at least some of the pairs contains noise and the corresponding target aerial image is noise-free. Noise-free target aerial images can, for example, be obtained using a simulation or by averaging noisy source aerial images. As the target aerial image is not obtained from the source image, this method is applicable for non-iid noise. In this way, the accuracy of the predictions of the machine learning model for reducing a noise level of an aerial image is improved.

In an example, the source aerial image and the corresponding target aerial image of at least some of the pairs contain noise of a different level. Since the target image corresponds to a different realization of the same underlying noise model, no iid-assumption for the noise is required and, thus, this method is applicable to non-iid noise. In this way, the generation of training data is simplified as noise-free aerial images are usually not available or have to be simulated.

In an example, the target aerial image of at least some of the pairs is obtained by processing the corresponding source aerial image, e.g., by replacing pixels or by subsampling. In this way, the generation of training data is simplified as noise-free aerial images are usually not available or have to be simulated.

According to a preferred example, the machine learning model for reducing a noise level of an aerial image is trained jointly with a machine learning model for defect detection in an aerial image of a photolithography mask. To this end, the training data comprises defect annotations, and the loss function is a joint loss function that evaluates the prediction accuracy of the machine learning model for reducing a noise level and of the machine learning model for defect detection. By training both machine learning models jointly, the prediction accuracy of the machine learning model for defect detection is improved, since the denoised aerial image are specifically adapted to a successful defect detection.

According to an example, the bit depth of the weights of a trained machine learning model is reduced after training. In this way, computation time and memory space is reduced.

According to a fifth embodiment of the invention, a method for generating training data for training a machine learning model for reducing a noise level of an aerial image of a photolithography mask comprises: scanning the photolithography mask in swaths using an inspection system to obtain an aerial image of the photolithography mask, the swaths having a width less than the width of the photolithography mask and corresponding to a field of view of the inspection system, wherein consecutive swaths partially overlap; and generating training data by obtaining pairs of source aerial images and corresponding target aerial images from images of overlap areas of consecutive swaths. Overlap areas of consecutive swaths contain the same structures of the photolithography mask with different noise realizations. Thus, they are particularly well suited for generating training data for a machine learning model for reducing a noise level of an aerial image.

The photolithography mask can contain markers in the overlap areas to align consecutive swaths. In this way, the accuracy of the predictions of the machine learning model for reducing a noise level of an aerial image is improved due to more data of good quality becoming available for training the machine learning models.

In an example, a source aerial image is obtained by selecting a subsection of an image of one of the swaths within the overlap area of consecutive swaths, and the corresponding target aerial image is obtained by selecting a subsection of the image of the other swath that shows the same or similar structures of the photolithography mask as the source aerial image. In particular, the corresponding target aerial image is the subsection of the image of the other swath of the consecutive swaths that overlaps with the source aerial image. In this way, machine learning models for reducing a noise level of an aerial image can be trained using source and target images with the same or similar structures but different noise realizations, leading to an improved prediction accuracy.

According to an aspect of the invention, a source aerial image is obtained by selecting a subsection of an image of one of the swaths within the overlap area of consecutive swaths, and the corresponding target aerial image is obtained by averaging the source aerial image and the overlapping subsection of the image of the other swath of the consecutive swaths. By averaging, the noise level of the target aerial image is reduced such that the target aerial image has a lower noise level than the source aerial image. In this way, the prediction accuracy is improved due to the training data of higher quality.

The machine learning model for reducing a noise level of an aerial image according to the fourth embodiment of the invention can be trained using training data generated according to a method of the fifth embodiment of the invention.

The generated training data according to the fifth embodiment of the invention can be used for training a machine learning model for reducing a noise level of an aerial image of a photolithography mask according to the fourth embodiment of the invention.

The method for reducing a noise level of an aerial image of a photolithography mask according to the first, second or third embodiment of the invention can use a machine learning model for reducing a noise level of an aerial image that is trained using a method according to the fourth embodiment of the invention. This method can be trained using training data generated using a method according to the fifth embodiment of the invention.

The method for training a machine learning model for reducing a noise level of an aerial image can be used in a method for detecting defects in a photolithography mask according to the first, second or third embodiment of the invention.

A computer-readable medium according to a sixth embodiment of the invention stores a computer program executable by a computing device, the computer program comprising code for executing a method for training a machine learning model for reducing a noise level of an aerial image according to a fourth embodiment of the invention.

A computer program product according to a seventh embodiment of the invention comprises instructions which, when the program is executed by a computer, cause the computer to carry out a method for training a machine learning model for reducing a noise level of an aerial image according to a fourth embodiment of the invention.

A system for defect detection in a photolithography mask according to an eighth embodiment of the invention comprises: an optical system configured to acquire an aerial image of the photolithography mask; one or more processing devices; one or more machine-readable hardware storage devices comprising instructions that are executable by one or more processing devices to perform operations comprising any one of the methods of claims.

The invention described by embodiments, examples and aspects is not limited to the embodiments, examples and aspects, but can be implemented by those skilled in the art by various combinations or modifications thereof.

### DESCRIPTION OF DRAWINGS

FIG. 1 illustrates an exemplary transmission-based optical system, e.g., a deep ultraviolet (DUV) optical system;

FIG. 2 illustrates an exemplary reflection-based optical system, e.g., an extreme ultra-violet light (EUV) optical system;

FIG. 3 illustrates a noisy aerial image of a photolithography mask containing a corner defect;

FIG. 4 illustrates a flowchart of a method for detecting defects in a photolithography mask;

FIG. 5 illustrates the method for detecting defects in a photolithography mask according to the first embodiment of the invention;

FIG. 6 illustrates a machine learning model for reducing a noise level of an aerial image in the form of an encoder-decoder architecture, here a U-Net, that is used for reducing a noise level of an aerial image of a photolithography mask, that can process additional information provided;

FIG. 7 illustrates a variant of the machine learning model for reducing a noise level of an aerial image, that receives an aerial image and a reference image and reduces the noise level of the aerial image to that of the reference image or that reduces the noise level of the reference image to that of the aerial image or that reduces both the noise level of the aerial image and the noise level of the reference image to the same noise level;

FIG. 8 illustrates a machine learning model for reducing a noise level of an aerial image in the form of a conditional diffusion model for reducing a noise level of an aerial image of a photolithography mask;

FIG. 9 illustrates a flowchart of a method for reducing a noise level of an aerial image of a photolithography mask using a set of specialized machine learning models for reducing a noise level of an aerial image;

FIG. 10 illustrates a flowchart of a method for reducing a noise level of an aerial image of a photolithography mask using a set of specialized machine learning models for reducing a noise level of an aerial image without determining the noise level of the aerial image;

FIG. 11 shows a flowchart of a method for detecting defects in an aerial image of a photolithography mask according to a second embodiment of the invention;

FIGS. 12A-12I shows results of a method for detecting defects in an aerial image of a photolithography mask for a corner defect according to a second embodiment of the invention;

FIGS. 13A and 13B compares a probability of detecting a defect for a template matching defect detection algorithm without and with prior denoising for a wide range of half pitch sizes and relative defect sizes;

FIG. 14 shows a method for detecting defects in an aerial image according to the third embodiment of the invention that further comprises a verification of the denoised aerial image;

FIG. 15 shows a flowchart of a computer implemented method for training a machine learning model for reducing a noise level of an aerial image of a photolithography mask according to a fourth embodiment of the invention;

FIG. 16 illustrates a machine learning model for reducing a noise level of an aerial image in the form of a U-Net;

FIG. 17 illustrates a joint machine learning model for reducing a noise level and defect detection with a sequential structure;

FIG. 18 illustrates a joint machine learning model for reducing a noise level and defect detection with a denoising head and a defect detection head;

FIG. 19 shows the process of scanning a photolithography mask in swaths with an inspection tool to generate an aerial image;

FIG. 20 illustrates a flowchart of a method for generating training data for training a machine learning model for reducing a noise level of an aerial image of a photolithography mask according to a fifth embodiment of the invention;

FIG. 21 illustrates the generation of source aerial images and target aerial images from the overlap area of consecutive swaths; and

FIG. 22 shows a system for detecting defects in a photolithography mask according to an eighth embodiment of the invention.

### DETAILED DESCRIPTION

In the following, advantageous exemplary embodiments of the invention are described and schematically shown in the figures. Throughout the figures and the description, same reference numbers are used to describe same features or components.

The methods and systems herein can be used with a variety of optical systems 10, 10′, e.g., transmission-based optical systems or reflection-based optical systems such as EUV systems.

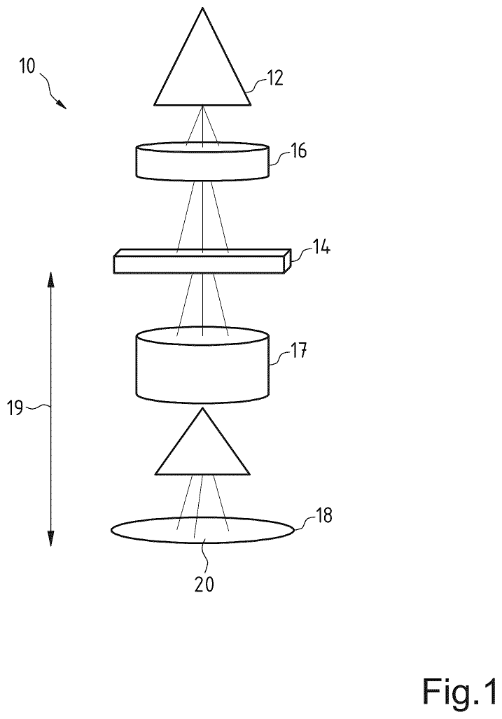

FIG. 1 illustrates an exemplary transmission-based optical system 10, e.g., a DUV photolithography system. Major components are a light source 12, which may be a deep-ultraviolet (DUV) excimer laser source, imaging optics which, for example, define the partial coherence and which may include optics that shape radiation from the light source 12, a photolithography mask 14, illumination optics 16 that illuminate the photolithography mask 14 and projection optics 17 that project an image of the photolithography mask design onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin(θₘₐₓ), wherein n is the refractive index of the media between the substrate and the last element of the projection optics 17, and θₘₐₓ is the largest angle of the beam exiting from the projection optics 17 that can still impinge on the wafer plane 18. The radiation distribution at the wafer plane 18 is imaged by an image sensor 20 of a camera to generate an aerial image. The optical system 10 can, for example, be equipped with a staring array sensor or a line-scanning sensor or a time-delayed integration (TDI) sensor.

In the present document, the terms “illumination”, “radiation” or “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 3-100 nm).

Illumination optics 16 may include optical components for shaping, reducing and/or projecting radiation from the light source 12 before the radiation passes the photolithography mask 14. Projection optics 17 may include optical components for shaping, reducing and/or projecting the radiation after the radiation passes the photolithography mask 14. The illumination optics 16 exclude the light source 12, the projection optics exclude the photolithography mask 14.

Illumination optics 16 and projection optics 17 may comprise various types of optical systems, including refractive optics, reflective optics, apertures and catadioptric optics, for example. Illumination optics 16 and projection optics 17 may also include components operating according to any of these design types for directing, shaping or controlling the projection beam of radiation, collectively or singularly.

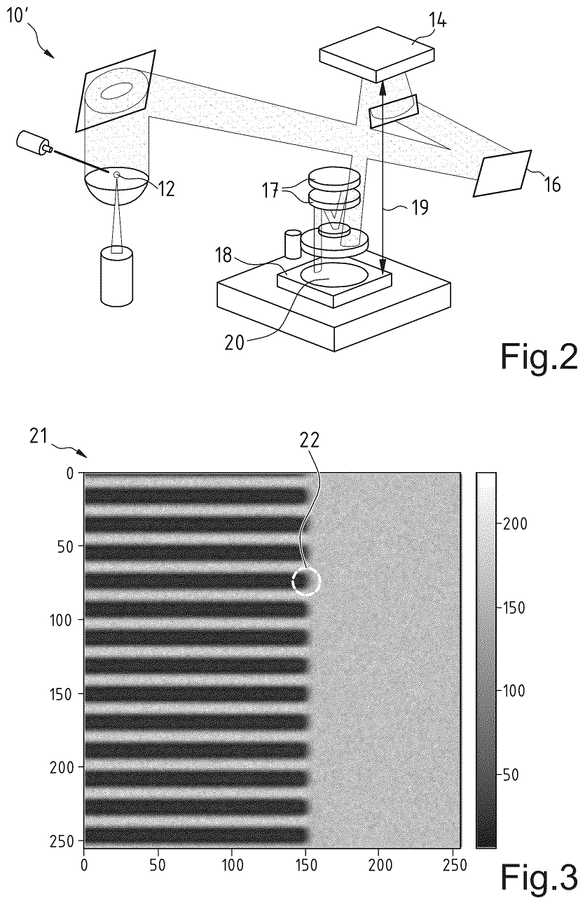

FIG. 2 illustrates an exemplary reflection-based optical system 10′, e.g., an extreme ultraviolet light (EUV) lithography system. Major components are a light source 12, which may be a laser plasma light source, illumination optics 16 which, for example, define the partial coherence and which may include optics that shape radiation from the light source 12, a photolithography mask 14, and projection optics 17 that project an image of the photolithography mask design onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin(θₘₐₓ), wherein n is the refractive index of the media between the substrate and the last element of the projection optics 17, and θₘₐₓ is the largest angle of the beam exiting from the projection optics 17 that can still impinge on the wafer plane 18. The radiation distribution at the wafer plane 18 is imaged by an image sensor 20 of a camera to generate an aerial image. The optical system 10′ can, for example, be equipped with a staring array sensor or a line-scanning sensor or a time-delayed integration (TDI) sensor.

An optical system 10, 10′, e.g., a mask inspection system, a mask qualification system or a metrology system such as the ones shown in FIGS. 1 and 2, can be used to generate an aerial image of the photolithography mask.

An aerial image refers to the image that is formed by the projection of light, e.g., of EUV or DUV wavelength, through a photolithography mask onto an imaging sensor, e.g., CCD or CMOS arrays. The imaging sensor can be part of a camera adapted for acquiring images at predetermined wavelengths. The camera can be an EUV camera, and/or a camera comprising a TDI sensor. In preferred embodiments, an image acquisition method comprises the use of an EUV camera comprising a TDI sensor. The camera's image sensor can accordingly be an EUV image sensor, i.e., an image sensor that is sensitive to EUV light. EUV light is light in the extreme ultraviolet spectral range with wavelengths between 5 nm and 100 nm, in particular with wavelengths between 5 nm and 30 nm. Especially the EUV light can have a wavelength of 13.5 nm. The EUV camera can be adapted for use in a photolithography mask inspection system, wherein the photolithography mask is projected onto an EUV image sensor of the EUV camera. In preferred embodiments, the image acquisition method comprises illuminating a photolithography mask with actinic radiation within the EUV wavelength range. EUV radiation reflected from the mask is then projected on an imaging sensor of an EUV camera via accordingly adapted projection optics.

The aerial image of the photolithography mask can be acquired by the optical system using light of an actinic wavelength. Mask inspection using light of an actinic wavelength means that the light used for the inspection is of the same wavelength as during the photolithography process.

Mask inspection with actinic wavelength has several benefits, including: a) a high contrast and resolution of the acquired aerial image, b) an improved sensitivity to defects that will print on the wafer during the photolithography process, c) an improved detection of phase defects in the multilayer of extreme ultraviolet (EUV) photolithography masks on both pattern mask and blank mask, which is difficult to achieve using deep ultraviolet (DUV) inspection systems.

During acquisition of the aerial image, noise from various sources degrades the quality of the aerial image.

A dominant source of noise in aerial images is shot noise due to the low illumination power and the short exposure times. Shot noise originates from the quantum properties of light and the discrete nature of photons. It can be modeled by a Poisson process. Shot noise may be dominant when the finite number of particles that carry energy such as electrons in an electronic circuit or photons in an optical device is sufficiently small so that uncertainties due to the Poisson distribution, which describes the occurrence of independent random events, are significant.

Other sources of noise include sensor noise such as dark current noise and stray light noise and noise due to signal processing such as clipping, quantization or data transfer.

Depending on the type of optical system, particularly high or low noise levels are common in the aerial images. In case of inspection systems, aerial images usually exhibit high noise levels (low signal-to-noise ratios) due to the low illumination power and short exposure times. A signal-to-noise ratio of an aerial image acquired by an inspection system is often below 10 dB, or even below 7 dB or 5 dB. Successfully training a machine learning model for reducing a noise level of aerial images of such high noise levels is difficult. In case of optical mask qualification systems or metrology systems, the aerial images are acquired with a higher photon count to improve their quality for mask qualification. For such optical systems, aerial images usually exhibit low noise levels (high signal-to-noise ratios). A signal-to-noise ratio of an aerial image acquired by a mask qualification system or metrology system is often above 30 dB, or even above 40 dB % or 60 dB. Successfully training a machine learning model for reducing a noise level of aerial images of such low noise levels is difficult as well.

A signal-to-noise ratio (SNR) of an aerial image refers to the ratio of the power of the image signal and the power of image noise. It measures the quality of the aerial image. SNR can be computed on a decibel scale [dB] according to the equation

$$SNR [ dB ] = 10 log 10 ( \frac{{P}_{s}}{{P}_{N}} ) = 10 ( log 10 ( {P}_{s} ) - log 10 ( {P}_{N} ) )$$

where P_{S} is the power of the image signal and P_{N} is the power of the image noise. FIG. 3 illustrates a noisy aerial image 21 of a photolithography mask 14 containing a corner defect 22. The aerial image can be acquired by an optical system 10, 10′ as illustrated with respect to FIGS. 1 and 2. An aerial image is the radiation intensity distribution at substrate level. It can be used to simulate the radiation intensity distribution generated by a photolithography mask during the photolithography process.

The term “defect” refers to a localized deviation of a structure of a photolithography mask from an a priori defined norm of the structure. The norm of the structure can be defined by one or more corresponding reference objects or reference datasets, e.g., by design datasets, simulated datasets or acquired defect-free datasets. A defect of a structure of a photolithography mask can result in malfunctioning of a corresponding manufactured semiconductor device. Depending on the detected defect the photolithography process can be improved, or photolithography masks can be repaired or discarded. Various defect detection methods are known to a person skilled in the art and are described below.

However, the quality of the detected defects directly depends on the quality of the aerial image. The quality of the aerial image is strongly degraded by noise. To this end, the method according to the invention reduces a noise level of the aerial image before detecting defects.

Noise in an aerial image can be reduced by averaging more than one aerial image of the same section of the photolithography mask. The variance of the noise decreases proportionally to the number of aerial images used for the averaging. However, acquiring multiple aerial images of the same section is time-consuming, reduces the throughput of the optical system, raises the mask inspection costs due to the increased power source energy and source consumables, especially in case of extreme ultraviolet (EUV) sources, and reduces the lifetime of the optical system. These problems can be alleviated by reducing the noise level using only a single aerial image.

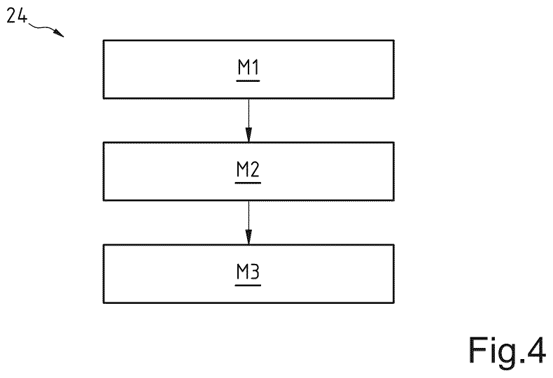

A method 24 for detecting defects in a photolithography mask according to the first embodiment of the invention is illustrated in FIG. 4. The method comprises: acquiring an aerial image of the photolithography mask using an optical system in a step M1; denoising the acquired aerial image using a machine learning model that is trained to reduce a noise level of an aerial image in a step M2; and detecting defects in the photolithography mask using the denoised aerial image in a step M3.

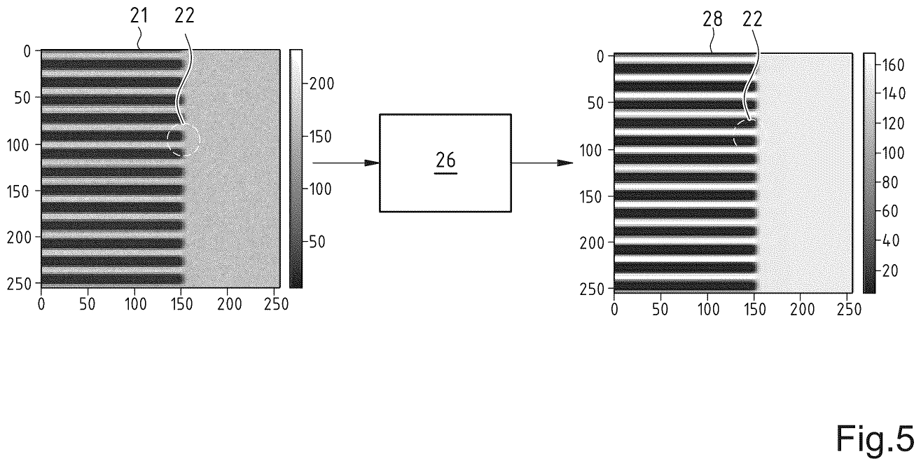

FIG. 5 illustrates the method 24 for detecting defects in a photolithography mask 14 according to the first embodiment of the invention. An aerial image 21 is acquired using an optical system 10, 10′. The aerial image 21 is used as input of a machine learning model 26. The machine learning model 26 is trained to reduce the noise level of the aerial image 21 yielding a denoised aerial image 28. The denoised aerial image 28 improves the detectability of defects 22, e.g., due to an improved contrast of the structures in the denoised aerial image 28.

Different machine learning models can be used for reducing a noise level of an aerial image, e.g., deep learning models, encoder-decoder architectures, Variational Autoencoders, CNNs, U-Nets, Transformers, Diffusion models, etc. Preferably, deep learning models are used for reducing a noise level of an aerial image to achieve a high accuracy of the predictions. Variational Autoencoders have the advantage that they additionally learn a model of the noise characteristics that allows to estimate pixel-specific denoising uncertainty.

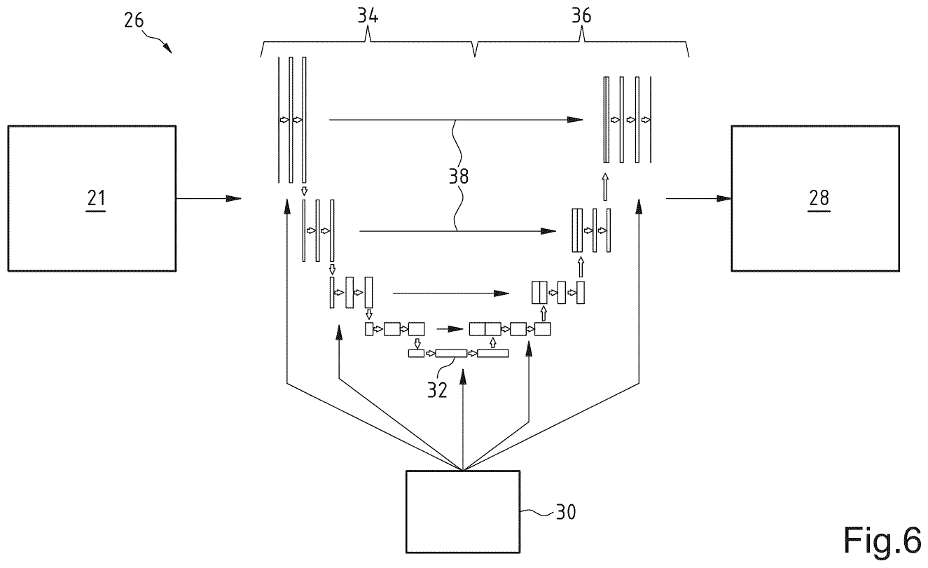

In FIG. 6, the aerial image 21 is used as input to the machine learning model 26 for reducing a noise level of an aerial image. The machine learning model 26 for reducing a noise level of an aerial image is a deep learning model, in particular an encoder-decoder architecture, in this case a U-Net. An advantage of using a U-Net is it is fast to apply and stable during training due to the one-to-one mapping of the noisy aerial image 21 to the denoised aerial image 28. The U-Net comprises an encoder 34, a decoder 36 and a bottleneck 32. The bottleneck 32 is an interface between the encoder 34 and the decoder 36. Thus, it belongs to the encoder 34 and to the decoder 36. The encoder 34 maps the input into a code, and the decoder 36 maps the code to an output, here the predicted denoised aerial image 28. The encoder 34 and the decoder 36 can be trained to minimize a difference between the predicted denoised aerial images 28 and corresponding clean training images without noise. The encoder 34 gradually reduces the dimensionality of the aerial image 21 until the bottleneck 32, thereby compressing the information contained in the aerial image 21 to the most relevant information for the denoising task. The code generated in the bottleneck 32 is a representation of the aerial image 21 of lower dimensionality and can, thus, be viewed as a compressed version of the aerial image 21. The decoder 36 gradually transforms the code in the bottleneck 32 to the output, i.e., to the denoised aerial image 28. Skip connections 38 allow the decoder 36 to directly access different levels of abstraction of the aerial image 21, thereby allowing to preserve small details of the aerial image 21 in the output.

In an example, additional information is provided as one or more additional inputs 30 to the machine learning model 26 for reducing a noise level of an aerial image. Additional information can comprise one or more of a noise level of the aerial image (potentially an estimation of the noise level), a design of the photolithography mask, a reference image, image acquisition information such as an image type, a machine type, an acquisition time, a photon count, or photolithography mask information such as one or more materials of the photolithography mask, refractive indices, a maximum or minimum feature size, etc. As illustrated in FIG. 6, the one or more additional inputs 30 can be provided in different locations of the machine learning model 26 for reducing a noise level of an aerial image, for example, in the input layer or in a hidden layer of a neural network, e.g., in the bottleneck of an encoder-decoder architecture. The additional input can comprise two or multiple information, e.g., a design of the photolithography mask and an estimated noise level of the acquired aerial image. Different additional inputs 30 could be provided in different locations of the machine learning model, e.g., a design of the photolithography mask in one of the layers of the encoder of the encoder-decoder architecture or in the input layer, and an estimated noise level in the bottleneck of the encoder-decoder architecture in FIG. 6.

A noise level of an aerial image can be estimated in different ways. For example, multiple aerial images of the same section of a photolithography mask can be acquired, and the standard deviation of the pixel value per pixel can be used as estimated noise level. For a single aerial image, the noise level can be estimated in different ways. For example, the variance of the pixel values within homogeneous regions can be used as noise estimate. Alternatively, the smallest eigenvalue of the covariance of low rank patches can be used as noise estimate.

According to an example, a design of the photolithography mask is provided as an additional input 30 to the machine learning model 26 for reducing a noise level of an aerial image. The design can be used to resolve ambiguities in the noisy aerial image. The noisy aerial image can be obscured and/or of a lower contrast leading to a loss of information. Therefore, there is no unique mapping from a noisy aerial image to a corresponding denoised aerial image. There can be multiple noisy aerial images that could lead to the same denoised aerial image. To obtain a unique solution, i.e., a unique denoised aerial image from the noisy aerial image, a design of the photolithography mask can be used as additional source of information. For example, the course of a straight edge can be unclear in a noisy aerial image and can be derived from the design. Thus, using the design of the photolithography mask as additional input 30 the machine learning model for reducing a noise level of an aerial image can be trained to resolve ambiguities in the denoised aerial image 28.

A design of a photolithography mask refers to a representation of properties of the photolithography mask or a section thereof. The design can, for example, comprise a computer readable file, such as a computer aided design (CAD) file or a graphic data system (GDS) file, or a technical drawing, a set of polygons representing the structures of the photolithography mask or a section thereof. A design of a photolithography mask can comprise an image, e.g., a 2D image or a 3D image (e.g., a volume of voxels or a number of 2D slices of a volume), that represents properties of the photolithography mask. The image can contain one, two or more channels. The image can comprise image elements, e.g., pixels or voxels. The properties of the photolithography mask can comprise material properties, e.g., refractive indices, electric permittivities, magnetic permeabilities, or derived representations. A design of a photolithography mask can comprise descriptions of the structures within the photolithography mask, e.g., in the form of curves, contours, polygons, Splines, NURBS, Bézier curves, etc. A design of a photolithography mask can comprise parameters describing dimensions of structures in the photolithography mask, e.g., the thicknesses of layers in a multilayer of an EUV mask or the thickness of absorber layers, or the dimension of absorber structures. A design of a photolithography mask can comprise parameters describing the location of structures in the photolithography mask, e.g., the location of absorber structures or layers in the multilayer. A design of a photolithography mask can comprise parameters describing the shape of structures in the photolithography mask, e.g., the shape of absorber structures such as side wall angles or corner rounding, etc. In an embodiment, the term “design” may exclude any representation that merely indicates edges or contours of structures or patterns of the photolithography mask, such as an edge map. In an embodiment, the term “design” may not include derived representations such as edge maps, gradient maps, or other data generated by post-processing or analysis of the design or of the corresponding mask image.

One or more additional inputs 30 can also be provided to the machine learning model 26 for reducing a noise level of an aerial image using, for example, cross-attention layers. Cross-attention layers transform their input into a new representation called attention-based representation by processing or paying attention to, another data source, here the one or more additional inputs 30. A rasterized design image can, for example, be combined with the acquired aerial image 21 via cross-attention layers in the input layer to generate an additional input 30 of the machine learning model 26 for reducing a noise level of an aerial image. Compared to CNNs, cross-attention layers are not limited to convolutions within local neighborhoods but take into account large parts or the whole additional source of information. In addition, the weights of the cross-attention layers are not fixed after training, but depend on the additional source of information, i.e., on the one or more additional inputs 30 of the machine learning model for reducing a noise level of an aerial image. Thus, cross-attention layers are particularly flexible in taking into account an additional source of information, yielding highly accurate predictions of the machine learning model for reducing a noise level of an aerial image.

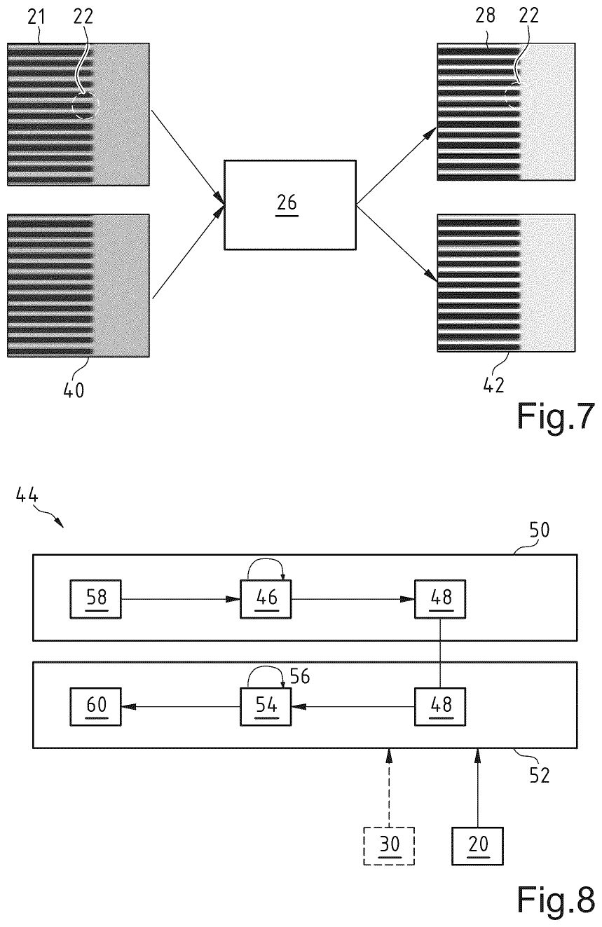

According to an example of the invention illustrated in FIG. 7, a reference image 40 of the photolithography mask is provided as an additional input 30 to the machine learning model 26 for reducing a noise level of an aerial image, and the machine learning model 26 for reducing a noise level of an aerial image is trained to denoise at least one of the aerial image 21 and the reference image 40 such that the noise levels approximately match. In a preferred example, the noise is approximately removed from the aerial image 21 and from the reference image 40. The noise level of the aerial image 21 can be reduced to the noise level of the reference image 40, or the noise level of the reference image 40 can be reduced to the noise level of the aerial image 21, or the noise level of the aerial image 21 and the noise level of the reference image 40 can both be reduced to a different noise level, e.g., to a target noise level. The noise level (or an estimated noise level) of the aerial image 21 and/or the noise level (or an estimated noise level) of the reference image 40 and/or a target noise level can be provided as an additional input 30 to the machine learning model as described with respect to FIG. 6. The denoised aerial image 28 and the denoised reference image 42 have the same noise level close to 0. Thus, they can be compared with higher accuracy, allowing for defect detections of higher accuracy and increased sensitivity. For example, a difference image of the denoised aerial image 28 and the denoised reference image 42 would contain defects and a very low noise level, whereas a difference image of the aerial image 21 and the reference image 40 would yield large differences over the whole image due to the high noise level.

A reference image 40 refers to an image of a photolithography mask or of a section thereof, that represents at least approximately the same structures as the aerial image of the photolithography mask. The reference image can be an aerial image or a different type of image such as a SEM image or a design image. A reference image 40 can comprise an acquired aerial image of the same photolithography mask, e.g., at a different point in time, using a different optical system, using the same optical system with different settings, using a different section of the same photolithography mask that contains at least approximately the same structures, etc. A reference image 40 can comprise an acquired aerial image of a different photolithography mask comprising at least approximately the same structures as the aerial image of the photolithography mask. A reference image 40 can comprise a simulated aerial image. An aerial image can be simulated from a design of a photolithography mask using aerial image simulation methods. For example, rigorous simulation methods such as finite difference time domain (FDTD) or rigorous coupled wave analysis (RCWA) can be used that are known to a person skilled in the art. Since they require long computation times, fast but less accurate approximations such as the thin element approximation (TEA) that relies on a thin mask assumption can be used. To obtain fast and accurate results, simulation methods that are based on physical models but still do not rely on the thin mask assumption can be used, e.g., the not quite rigorous method (NQR) method disclosed in PCT application No. WO 2024 141484 A1 and in German patent application No. DE 10 2022 135019 A1, the entire contents of the above applications are herein incorporated by reference. Apart from physical simulations, trained machine learning models can be used to simulate aerial images from designs. A reference image 40 can comprise a so-called golden reference, e.g., an image of a defect-free photolithography mask. A reference image 40 can comprise a representation of the structures of the photolithography mask, e.g., a design of the photolithography mask or a derived representation of a design.

In another example, the machine learning model for reducing a noise level of an aerial image comprises a conditional diffusion model that sequentially reverts a stochastic process and that is trained to decrease a noise level of the input image in each stochastic process step. Diffusion models have the advantage that they do not necessarily have to be trained on aerial images but can also be trained on other images and applied without adaptation to aerial images. In this way, a training and re-training of the machine learning model for reducing a noise level of an aerial image can be prevented, thereby saving a lot of effort and time. Instead, the adaptation happens at inference time. Inference can, however, take longer, since the reverse stochastic process potentially has to be applied more often to achieve the desired result.

A diffusion model 44 illustrated in FIG. 8 comprises a generative machine learning model that is configured to sequentially revert a stochastic process 50, preferably a diffusion process, using a reverse stochastic process 52. In this case, the stochastic process is a denoising process. The diffusion model 44 is configured to learn a distribution of images, here of noise-free or denoised aerial images. During training, the diffusion model 44 applies one or more stochastic process steps 46 to a noise-free aerial image 58. This is known as the stochastic process 50, which is used only during training of the diffusion model 44. The stochastic process 50 gradually results in samples 48 that are farther from the learned distribution of noise-free aerial images 58, i.e., that contain more noise. The stochastic process 50 is then reversed in a reverse stochastic process 52 to recover the original noise-free aerial image 58 by sequentially 56 applying a reverse stochastic process step 54 to the sample 48 yielding a generated denoised aerial image 60. In this way, the diffusion model 44 learns to gradually remove the effect of the stochastic process 50, the noise, from the samples 48. During inference, only the reverse stochastic process 56 is applied to randomly generated initial samples 48 in order to generate denoised aerial images 60. Diffusion models are, for example, described in “Denoising Diffusion Probabilistic Models, J. Ho, A. Jain, P. Abbeel, 2020, arXiv 2006.11239”. Since the invention does not aim at generating arbitrary denoised aerial images 60, but denoised aerial images for a specific input aerial image 21, preferably a conditional diffusion model is used that is conditioned on the input aerial image 21. This is accomplished by using the input aerial image 21 as input to the reverse stochastic process 52. Apart from the input aerial image 21, additional information can, optionally, also be provided as a condition to the conditional diffusion model 44, i.e., as additional inputs 30 to the reverse stochastic process 52.

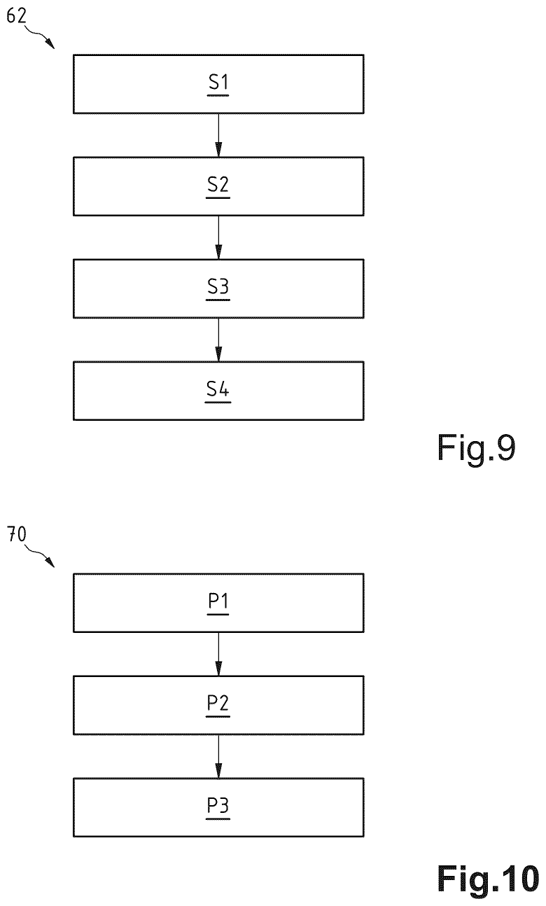

According to a flowchart shown in FIG. 9, instead of training a single machine learning model for reducing a noise level of an aerial image, a set of machine learning models for reducing a noise level of an aerial image is trained. Each machine learning model of the set of machine learning models is trained for a specific noise level interval of the acquired aerial image. The method 62 for denoising an aerial image of a photolithography mask comprises: acquiring an aerial image of a photolithography mask using an optical system in a step S1; determining the noise level of the acquired aerial image in a step S2; selecting a machine learning model from a set of machine learning models using the determined noise level, wherein each machine learning model of the set of machine learning models is trained to reduce the noise level of an aerial image of a photolithography mask for an aerial image of a noise level within a specific noise level interval in a step S3; and applying the selected machine learning model to the acquired aerial image in a step S4.

The set of machine learning models for reducing a noise level of an aerial image covers several noise level intervals. These noise level intervals can be of the same size, or they can differ in size. They can be evenly distributed over a predefined interval of expected noise levels of the aerial image, or they can be non-evenly distributed. The noise level intervals could, alternatively, be randomly distributed within the interval of expected noise levels, etc. In step S2, the noise level of the acquired aerial image can, for example, be determined using a measurement method, or it can be specified by a user, or it can be obtained from a database, etc. Selecting a machine learning model from the set of machine learning models in step S3 can, for example, comprise selecting the machine learning model whose noise level interval covers the determined noise level of the aerial image. Alternatively, two, three or more machine learning models could be selected for noise level intervals that are closest to the determined noise level of the aerial image. After applying these machine learning models to the aerial image the best result with respect to some image quality measure could be selected as aerial image with a reduced noise level.

Alternatively, the set of machine learning models can be used to reduce the noise level of an aerial image without determining the noise level of the aerial image as illustrated in the flowchart in FIG. 10. The method 70 for reducing a noise level of an aerial image of a photolithography mask comprises: acquiring an aerial image of a photolithography mask using an optical system in a step P1; applying two or more machine learning models from a set of machine learning models to the acquired aerial image yielding a set of denoised aerial images, wherein each machine learning model of the set of machine learning models is trained to reduce the noise level of an aerial image of a photolithography mask for an aerial image of a noise level within a specific noise level interval in a step P2; and selecting a denoised aerial image from the set of denoised aerial images using an image quality measure in a step P3.

The two or more applied machine learning models can comprise all machine learning models of the set of machine learning models. Alternatively, the two or more applied machine learning models can be randomly selected from the set of machine learning models. Alternatively, the two or more applied machine learning models can be selected according to some pattern from the set of machine learning models, e.g., a machine learning model can be selected for every second, third, fourth, etc., noise level interval. Alternatively, a fixed number of machine learning models can be selected from the set of machine learning models according to a decreasing likelihood of the corresponding noise level interval, i.e., a decreasing likelihood for a noise level of an aerial image to fall within the noise level interval, etc.

The machine learning model for reducing a noise level of an aerial image of a photolithography mask can be used to obtain a denoised aerial image more suitable for defect detection as illustrated in the flowchart of FIG. 4.

Various defect detection methods for aerial images are known to a person skilled in the art. For example, die-to-die methods and die-to-database methods can be used for defect detection. The defect detection methods are applied to the denoised acquired aerial image to obtain defect detection results of improved quality.

The die-to-die principle compares an acquired aerial image of a photolithography mask with a reference image in the form of another acquired aerial image of the same photolithography mask, e.g., of the same section or of another section containing the same or similar structures. The discovered deviations are treated as defects. This method is simple to implement, but it requires the availability and time-consuming scanning of two corresponding portions of a photolithography mask and exact knowledge about their relative position. In addition, it fails in case of systematic repeating defects.

The die-to-database principle compares an aerial image of a photolithography mask to a reference image from a database, e.g., a simulated aerial image, a golden reference, an acquired defect-free aerial image, a design or CAD file, thereby discovering deviations from the ideal data. Even defects in rare or uncommon structures or systematic repeating defects can be detected in this way. However, die-to-database methods require the availability of a reference image. In addition, they are computationally expensive since they require an intermediate registration step to align the aerial image and the reference image.

Defects can be detected by comparing the aerial image to the reference image, e.g., by computing a difference image. Thresholding techniques can be applied to the difference image, e.g., simple thresholds or adaptive thresholds.

Defect detection methods can include a trained machine learning model. The trained machine learning model for defect detection could use an aerial image or a pair of an aerial image and a corresponding reference image as input that is mapped to defect indicators. A machine learning model for defect detection can perform various tasks such as defect detection (presence or absence of a defect), defect localization (locating a defect), defect segmentation (computing the area, volume or outline of a defect), defect classification (assigning a defect class to a defect), etc. The machine learning model for defect detection can be trained using training data comprising aerial images and defect annotations, or pairs of aerial images and corresponding reference images and defect annotations.

Defect detection methods can include template matching methods. Template matching is a technique in digital image processing for finding small parts of an image which match a template image. Templates can include typical defect shapes in photolithography masks. Template matching can, for example, use correlation techniques that correlate sections of the aerial image with one or more templates to locate the one or more defects in the aerial image. In case a reference image is used, template matching can be applied to the difference image of the aerial image and the reference image. High correlation results, e.g., correlation results above a threshold, indicate the presence of the corresponding template in the image or difference image. The templates and corresponding thresholds can be defined by a user.

Defect detection methods can include filtering approaches. Filtering approaches convolve an aerial image with one or more filters. The one or more filters can be used to generate features from sections of the aerial image. Based on these features, classification methods can be applied that classify sections as defective or not. Filters can, for example, comprise edge detectors, Gabor filters, filters obtained from an intermediate layer of a trained convolutional neural network, Fourier filters, high-pass filters, HOG features, SIFT features, local binary pattern filters, etc.

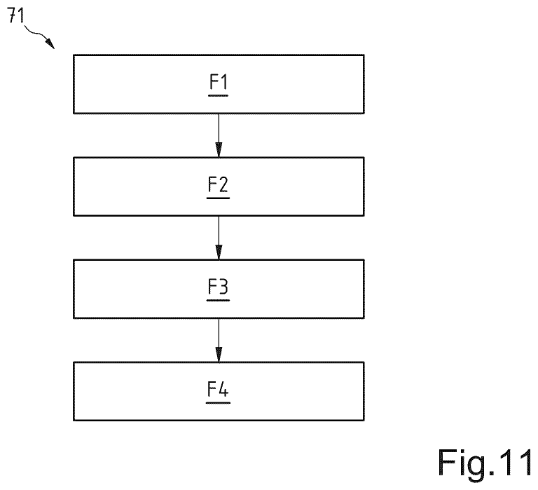

In case, a reference image is used for defect detection and the reference image is noisy, the noise level of the reference image could be reduced together with the noise level of the acquired aerial image as illustrated in FIG. 7. FIG. 11 shows a flowchart of a method 71 for detecting defects in an aerial image of a photolithography mask according to a second embodiment of the invention. The method comprises: acquiring an aerial image of photolithography mask using an optical system in a step F1; obtaining a reference image of the photolithography mask in a step F2; reducing at least one of the noise level of the aerial image and the noise level of the reference image such that the noise levels approximately match in a step F3; and applying a defect detection method to the denoised aerial image and the denoised reference image in a step F4.

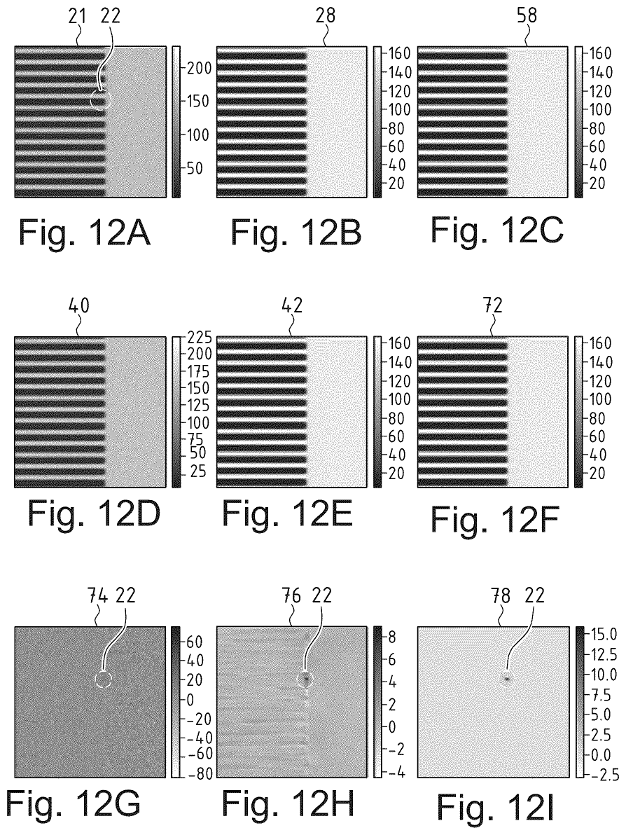

FIGS. 12A-12I show results of the method for denoising an aerial image according to the second embodiment of the invention. FIG. 12A shows a noisy aerial image 21 containing a corner defect 22. FIG. 12B shows a predicted denoised aerial image 28 with a reduced noise level of approximately 0. FIG. 12C shows the corresponding noise-free aerial image 58. FIG. 12D shows a noisy reference image 40, and FIG. 12E shows a predicted denoised reference image 42 with a reduced noise level of approximately 0. FIG. 12F shows the corresponding noise-free reference aerial image 72. FIG. 12G shows a difference image 74 of the noisy aerial image 21 and the noisy reference image 40. FIG. 12H shows a difference image 76 of the denoise aerial image 28 and the denoise reference image 42. FIG. 12I shows a difference image 78 the noise-free aerial image 58 and the noise-free reference image 42. The defect 22 is not visible in the difference image 74 of the noisy aerial image 21 and the noisy reference image 40. The visibility of the defect 22 is improved by denoising the aerial image 21 and the reference image 40 and computing their difference.

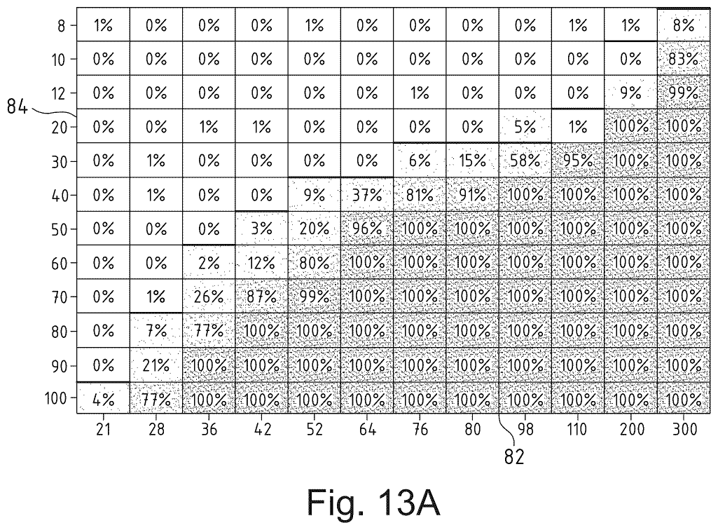

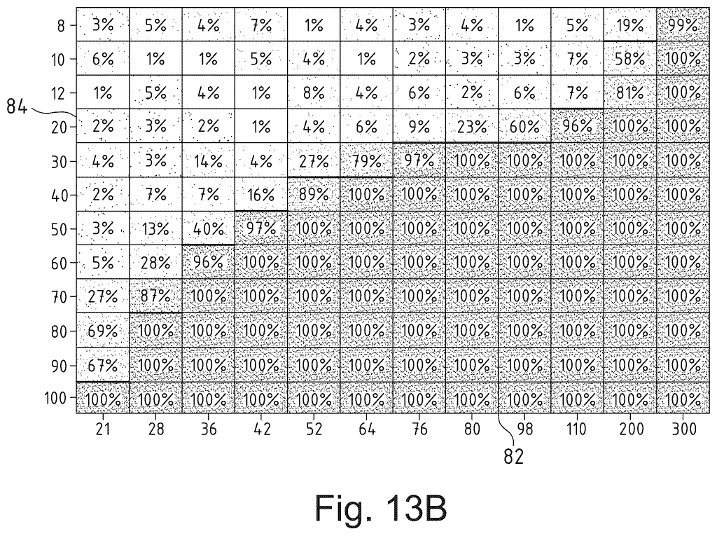

FIGS. 13A-13B compare a probability of detecting a defect for a template matching defect detection algorithm without and with prior denoising for a wide range of half pitch sizes and relative defect sizes for a corner-type defect. FIG. 13A shows the probabilities without prior denoising, FIG. 13B shows the probabilities with prior denoising. On the horizontal axis 82, the half pitch is shown, whereas on the vertical axis 84 the relative defect size in % is shown. Thus, each cell shows the probability of detecting a defect given a certain half pitch for a relative defect size. The highlighted cells indicate a required target sensitivity (20 nm on wafer). Thus, FIGS. 13A and B illustrate that without denoising, the target sensitivity is not reached for any of the half pitches, whereas after denoising the target sensitivity is reached close to 100% for almost all half pitches.

The noise characteristics of the aerial image may change over time during defect inspection, e.g., due to data drift, domain shifts or distribution shifts in a production environment, or due to changing environments, settings or conditions. Therefore, monitoring the quality of the denoised aerial image as well as data collection for potential re-trainings of the machine learning model for reducing a noise level of an aerial image is important, for example, in in-line inspection.

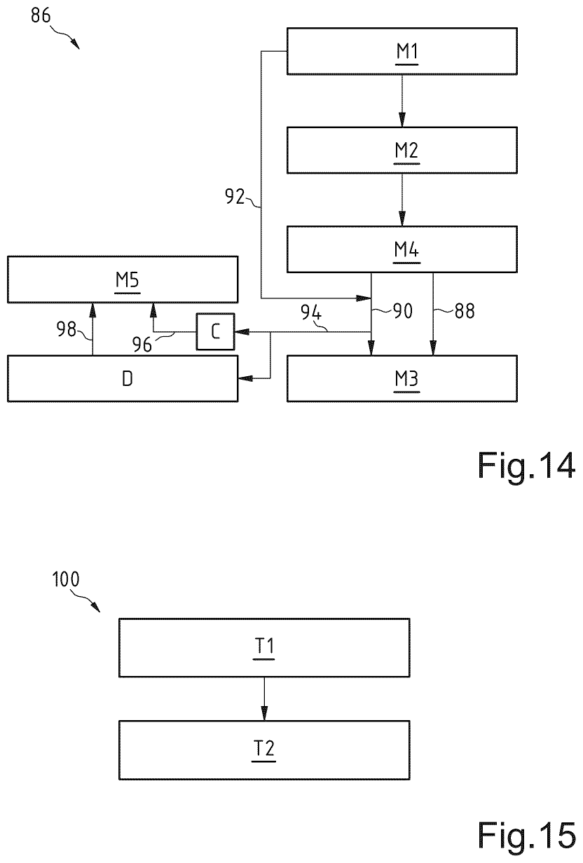

Therefore, in an example illustrated in FIG. 14, a method 86 for detecting defects in an aerial image according to the third embodiment further comprises verifying the reduction of the noise level of the denoised aerial image using an image quality criterion in a step M4. If the image quality criterion is fulfilled 88 the defect detection step M3 is carried out using the denoised aerial image as before. If the image quality criterion is not fulfilled 90, the quality of the denoised aerial image is deemed to be insufficient for defect detection. In this case, the original acquired aerial image 92 is used for detecting defects. Aerial images, for which the image quality criterion is not fulfilled, can be collected 94, e.g., in a database D, in order to re-train the machine learning model for reducing a noise level of an aerial image specifically on this set of collected aerial images.

In addition, the steps of the method can be repeated multiple times, and the number of images, for which the image quality criterion is not fulfilled, can be counted in a counter C. For example, the total number of images, for which the image quality criterion is not fulfilled 90 since the last (re-)training of the machine learning model or within a period of time can be counted, or the number of images in a row, for which the image quality criterion is not fulfilled 90, can be counted. With a growing number of images, for which the image quality criterion is not fulfilled, the likelihood for a change of the acquisition setting increases. Using the counter C, a condition can be formulated for initiating a re-training of the machine learning model, e.g., a threshold. Upon reaching this condition, a re-training of the machine learning model for reducing a noise level of an aerial image can be initiated 96 in a step M5. For example, a message that indicates a required re-training can be sent to a user or displayed on a screen. Alternatively, the machine learning model for reducing a noise level of an aerial image can be automatically re-trained. For re-training of the machine learning model for reducing a noise level of an aerial image, the collected aerial images are used 98. These can be stored in the database D.

The trained machine learning models for reducing a noise level of an aerial image can be stored in a database, e.g., in a model registry, as well. They can be labeled with specific properties of the setting, e.g., the time of day the training images were acquired, the pattern types in the training images, acquisition settings of the optical system, e.g., an illumination setting or a focus level, etc. Depending on the current setting, a corresponding machine learning model for reducing a noise level of an aerial image can be loaded with respect to its labels. For example, a different machine learning model for reducing a noise level of an aerial image can be trained for each illumination setting, etc., and upon changing the illumination setting, the corresponding machine learning model for reducing a noise level of an aerial image can be loaded from the database, e.g., from the model registry.

The image quality criterion can comprise comparing an estimated noise level and/or a measurement of preserved structure in the denoised aerial image and in the acquired aerial image. If the estimated noise level of the denoised aerial image is higher than the estimated noise level of the acquired aerial image, the image quality criterion is not fulfilled. If the measurement of preserved structure in the denoised aerial image is lower than in the acquired aerial image the image quality criterion is not fulfilled. The noise level can, for example, be estimated from a variance of pixel values within homogeneous regions, or by using the smallest eigenvalue of the covariance of low-rank patches.

The image quality criterion can, for example, comprise comparing the denoised aerial image with a reference image of a lower noise level. If the denoised aerial image contains less noise than the reference image, the image quality criterion is fulfilled.

In case, defects are detected in the denoised aerial image by comparing the denoised aerial image to a reference image, the image quality criterion can comprise comparing the denoised aerial image and the acquired aerial image to an estimated mean image of the acquired aerial image and the reference image. The estimated mean image can be obtained by applying a function to the acquired aerial image and the reference aerial image. The function can, for example, compute a pixel-wise mean value, a region-wise mean value, a patch-wise mean value, etc., but is not limited to that.

The estimated mean image is supposed to contain less noise than the acquired aerial image due to the averaging of the acquired aerial image and the reference image. Therefore, the deviation of the denoised aerial image from the estimated mean image should be lower than the deviation of the acquired aerial image from the estimated mean image. The image quality criterion can, thus, comprise as a condition C1 comparing the deviation of the denoised aerial image D from the estimated mean image M to the deviation of the acquired aerial image I from the estimate mean image M:

$$C 1 : Dev ( D , M ) < Dev ( I , M )$$

In case the noise level is improved by denoising, this condition is expected to be fulfilled.

At the same time, it is important to preserve the structures in the denoised aerial image. The structures in the denoised aerial image should be more similar to the estimated mean image than the structures in the acquired aerial image. Therefore, the image quality criterion can comprise a second condition C2 that compares a measurement of preserved structure, e.g., a structured similarity index measure (SSIM) that is used in computer vision to measure the similarity between two images:

$$C 2 : SSIM ( D , M ) > SSIM ( I , M )$$

The SSIM can be computed for the entire images or for a number of patches in the images, e.g., for randomly selected patches in the images. In case the structures in the denoised aerial image are preserved, this condition is expected to be fulfilled.

The image quality criterion can contain one or more conditions, e.g., the condition C1 and/or the condition C2.

In case of a die-to-die defect detection method, the reference image is obtained from another die of the same photolithography mask. In case of a die-to-database defect detection method, the reference image is obtained from some model, e.g., from a design of the photolithography mask, from a defect-free acquired aerial image, from a simulated aerial image, etc.

To speed up the denoising of the aerial image and/or the training of the machine learning model the algorithms can be ported to a graphics processing unit (GPU).

According to the fourth embodiment of the invention illustrated in FIG. 15, a computer implemented method 100 for training a machine learning model for reducing a noise level of an aerial image of a photolithography mask obtained by an optical system comprises: providing training data comprising pairs of source aerial images and corresponding target aerial images configured for training the machine learning model for reducing a noise level of an aerial image in a step T1; and training the machine learning model for reducing a noise level of an aerial image by minimizing a loss function using the training data in a step T2. In each pair of source aerial image and target aerial image, the source aerial image has a higher noise level than the target aerial image.

The machine learning model for reducing a noise level can be trained, for example, using the following loss function that contains a distance measure in spatial domain. Let S={S₁, . . . , Sₙ} indicate a set of n source aerial images and T={T₁, . . . , Tₙ} a set of n corresponding target aerial images. The source aerial images and the target aerial images differ in their noise realization. f_{θ}(Sᵢ) indicates the prediction of the machine learning model for reducing a noise level of an aerial image with model parameters e for aerial image Sᵢ. The machine learning model for reducing a noise level of an aerial image is trained by finding a set of parameters e that minimize a loss function. Such a loss function can take, for example, the following form:

$$L ( S , T ) = {\sum }_{i = 1}^{n} {\vert {f}_{θ} ( {S}_{i} ) - {T}_{i} \vert}_{m} .$$

The optimization can be carried out using, e.g., a variant of the backpropagation algorithm or the adaptive moment estimation (ADAM) optimization algorithm. ADAM is an optimization algorithm that builds upon the strengths of two other popular techniques: adaptive gradient algorithm (AdaGrad) and root mean square propagation (RMSProp). It is an adaptive learning rate algorithm that dynamically reduces the learning rate for each individual parameter within a machine learning model, rather than using a single global learning rate.

Most machine learning models for denoising derive information only from the spatial domain representation of the input images, while the information in the frequency domain is usually ignored. However, many optical systems have a finite numerical aperture and hence the signal measured by the optical system is bandwidth limited in the frequency domain. The numerical aperture of the optical system, which also defines the resolution limit, acts as a low pass filter. The effect of the low pass filter is that the relevant information of the imaged photolithography mask is contained within a finite range of frequencies. This range depends on the choice of illumination settings and the aperture shape of the objective lens or mirror of the optical system. At the same time, the noise is not band-limited and spread across the entire frequency spectrum. Therefore, the apparent differences between two noisy images can be seen across the entire spectrum in frequency domain, and most prominently at high frequency bands.

Therefore, the loss function comprises at least one term that is defined in the frequency domain. According to an example, the loss function comprises a distance measure in the frequency domain. Preferably, the loss function compares the frequency spectrum of the source aerial images and the corresponding target aerial images.

This is particularly beneficial in case of optical mask qualification systems or metrology systems that use a high photon count to generate aerial images of high quality with a low noise level. For such optical systems, it can be challenging to train a machine learning model for reducing a noise level using training images in the spatial domain. As noise is present over all frequency bands, in particular in high frequency bands that do not contain aerial image information, training the machine learning model for reducing a noise level using training images in the frequency domain improves the prediction accuracy, since small fluctuations in the spatial domain that are typical for aerial images with low noise levels have a more pronounced signal in the frequency domain. As the prediction accuracy is already improved for aerial images with low noise levels, this applies even more for aerial images with high noise levels generated by inspection systems that use low photon counts. Using distance measures in the frequency domain is also advantageous, since the training images do not have to be aligned, thus saving computation time and effort.

According to an example, the loss function comprises a distance measure of a target aerial image and a predicted denoised source aerial image in the frequency domain, wherein the predicted denoised source aerial image is obtained by presenting the corresponding source aerial image to the machine learning model for reducing a noise level of an aerial image. The loss function can also comprise a regularization term that measures a phase shift between a source aerial image and a predicted denoised source aerial image. A phase shift between a source aerial image and a predicted denoised source aerial image can, for example, be determined using a phase-correlation technique. For this purpose, a two-dimensional Fourier transform is computed for each image, and a cross-power spectrum is obtained by normalizing the product of one Fourier transform with the complex conjugate of the other. An inverse Fourier transform of the cross-power spectrum yields a correlation surface exhibiting a distinct peak, the position of which indicates the translational offset between the images.

This translational offset corresponds to the phase shift between the source aerial image and the predicted denoised source aerial image and can be determined with sub-pixel precision. The loss function can comprise a function of a distance measure of a target aerial image and a predicted denoised source aerial image in the frequency domain.

An exemplary loss function L can, for example, take the following form:

$$L ( S , T ) = {\sum }_{i = 1}^{n} log ( 1 + \vert F ( {f}_{θ} ( {S}_{i} ) - F ( {T}_{i} ) {\vert}_{m} ) + α {\vert {f}_{θ} ( {S}_{i} ) - {S}_{i} \vert}_{k}$$

where F denotes a complex valued 2D discrete Fourier transform and |·|k indicates the lₖ-norm. m and k can be any non-negative real number including infinity, for example, 1 or 2. By minimizing the lₘ distance between the source aerial image Sᵢ and the corresponding target aerial image Tᵢ in the frequency domain (in the spectrum), the machine learning model for reducing a noise level of an aerial image learns to map an input image to an output image with a similar spectrum, thereby discarding their differences that are due to noise. As differently aligned images produce the same spectrum magnitude in the frequency domain, the regularization term (second term) is used to prevent misalignment by penalizing deviations of the predicted denoised source aerial image fθ(Sᵢ) from the source aerial image Sᵢ. The regularization term is weighted by a factor α>0 that controls the influence of both terms on the prediction.

Various distance measures in the frequency domain can be used, for example, using an lₘ norm for any value of m as above, a distance of peak frequencies, a cross correlation of the two spectra, local or patch wise cosine distance, an Earth-Movers distance, a difference of the integrals of both spectra, etc. A weighted distance measure can be used that weighs differences outside the frequency bands of the image signal higher than within the frequency bands of the image signal. Various functions g of a distance measure d in the frequency domain can be used in the first term of the loss function L above, e.g., g(d)=1+log(d), g(d)=d^{j} for j∈ [symbol] , the Huber loss function, etc. Different regularization terms can also be used, e.g., an lₖ norm for any value of k as above, a distance in feature space, e.g., between edges in the predicted denoised source aerial image and the source aerial image, between filter responses in the predicted denoised source aerial image and the source aerial image (e.g., using Gabor filters, layers of trained convolutional neural networks, highpass or lowpass filters, edge filters), etc.

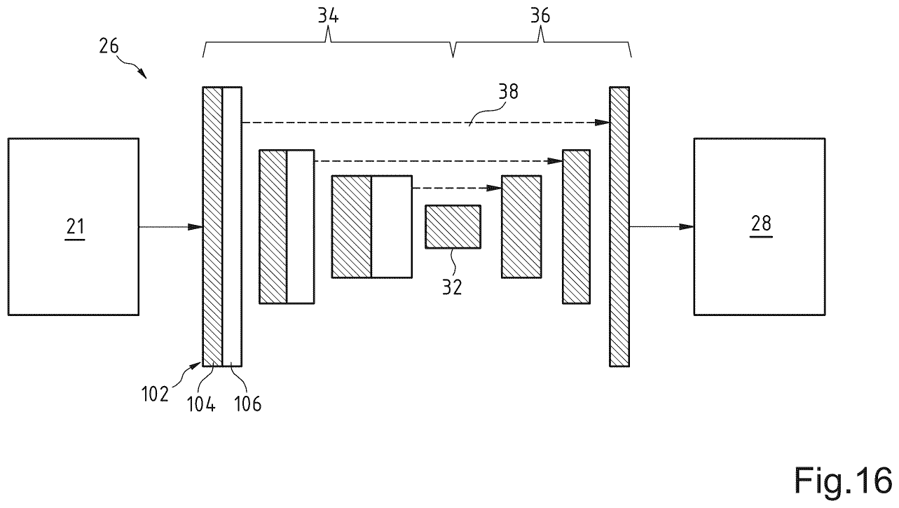

In a specific example illustrated in FIG. 16, the machine learning model 26 for reducing a noise level of an aerial image can, for example, be a U-Net comprising an encoder 34, a bottleneck 32, a decoder 36 and a number of skip connections 38 between corresponding encoder layers and decoder layers. The encoder 34 and decoder 36 have the same number of convolution blocks 102, in this case three. Each convolution block 102 comprises one or more convolution layers. Each of the encoder convolution layers 104 contains a dilated convolution layer 106 with the same number of features and a dilation of 2. In this way, the size of the receptive field of the encoder is enlarged. The number of features in the first encoder layer is 32.

In an example, the bias parameters in each convolution layer of the encoder 34 and the decoder 36 are set to 0. A rectified linear unit (ReLu) activation function is used after each convolution layer. Batch normalization or dropouts are not used in the training. The number of input and output channels is one, since the noisy aerial image 21 and the denoised aerial image 28 are grey-scale images. The U-Net is trained using training data comprising source aerial images and target aerial images. The source aerial images and the target aerial image comprise 256×256 pixel crops of aerial images. ADAM is used for optimization of the parameters of the machine learning model. The learning rate was set to 0.0005, the training was conducted for 200 epochs

The training data can comprise acquired aerial images of photolithography masks and/or simulated images of photolithography masks. Acquired aerial images are more realistic, e.g., including various noise levels, optical aberrations, focus levels, mask materials, structure types and image quality degradations, but their acquisition is often time-consuming, requires a huge user effort and bears the risk of not covering all relevant patterns, defects, noise levels, focus levels or image acquisition conditions to achieve a sufficient generalization ability of the machine learning model. Simulated input images are less realistic but are easily and quickly generated at large volumes requiring low user effort. In addition, they allow for a systematic and dense generation of images for various ranges of noise levels, integrated circuit pattern types, defect types, image acquisition conditions, image quality degradations, etc. The simulated aerial images can, for example, be obtained using simulations based on physical models such as RCWA, TEA or NQR, or using simulations based on machine learning models, e.g., diffusion models, or from design data, e.g., from CAD models, for example, by using a generative machine learning model that is conditioned on the design of a photolithography mask. Preferably, the training data comprises both acquired aerial images and simulated aerial images to achieve high prediction accuracy.

The training data, preferably, comprises different types of integrated circuit patterns, e.g., different types of semiconductor structures or photolithography mask structures such as lines and spaces, contact holes, logic patterns, etc., in order to achieve reliability of the method across different structure types. Preferably, the training data contains types of structures at different locations of the photolithography masks in order to learn spatially dependent denoising options.

The training data can comprise pairs of source aerial images of different noise levels and corresponding noise-free or denoised aerial images or aerial images of a target noise level as target aerial images. In this way, a higher prediction accuracy can be obtained. However, noise-free or denoised aerial images are often not available or require a lot of effort to obtain.

Additionally or alternatively, the training data can contain pairs of source aerial images of different noise levels and corresponding target aerial images of different noise levels. Even though both the source aerial images and the target aerial images are noisy, the machine learning model for reducing a noise level of an aerial image, nevertheless, learns a mapping between noisy aerial images and noise-free aerial images, provided the noise is zero-mean noise. In this way, the effort for generating training data is reduced as only aerial images of low SNR are required. Additionally or alternatively, at least some of the target aerial images can be computed from the source aerial images, e.g., by modifying one or more pixels in the source aerial images, by applying a function to one or more pixels of the source aerial images, or by subsampling a source aerial image in different ways, etc. For example, values of center pixels of patches are replaced by different values that are randomly selected from the patches, or from a distribution, or by the mean or median of the patch, etc.

The source aerial images should be acquired or simulated for different noise levels, preferably covering the range of expected noise levels in acquired aerial images. For example, the distribution of noise levels can reflect the distribution of noise levels in typical acquired aerial images. In this way, reliability of the method is achieved for different noise levels of the acquired aerial image.

Noise levels of the source aerial images and/or of the target aerial images can be saved to be used as additional input to the machine learning model for reducing a noise level of an aerial image.

The training data can, for example, comprise at least 20,000 pairs of source aerial images and corresponding target aerial images. The training data can be split into training data, test data and validation data, e.g., using a splitting ratio of 70%/15%/15%. The splitting of the training data is carried out in a stratified manner to ensure that all structure types and noise levels occur in the training data, test data and validation data. The validation data is used to measure the performance of the machine learning model on unknown data during training. It is used to control the training process and to prevent overfitting. The test data is used to measure the performance of the trained machine learning model.

The hyperparameters of the machine learning model for reducing a noise level of an aerial image can be optimized using the validation set and some hyperparameter optimization method known to a person skilled in the art.

Using the training data, the machine learning model for reducing a noise level of an aerial image of a photolithography mask can be trained. A machine learning model suitable for this task is, for example, an encoder-decoder architecture, e.g., a U-Net, as shown in FIG. 6 or a conditional diffusion model as shown in FIG. 8.

According to an example, the bit depth of the weights of a trained machine learning model, e.g., of a machine learning model for reducing a noise level and/or of the machine learning model for defect detection, is reduced after training, e.g., by quantization. This reduces memory requirements and increases the inference speed. The bit depth can, for example, be reduced to 8 or 16 or 32 bits. The bit depth of the machine learning model can also be reduced by quantization aware training on a small calibration dataset.

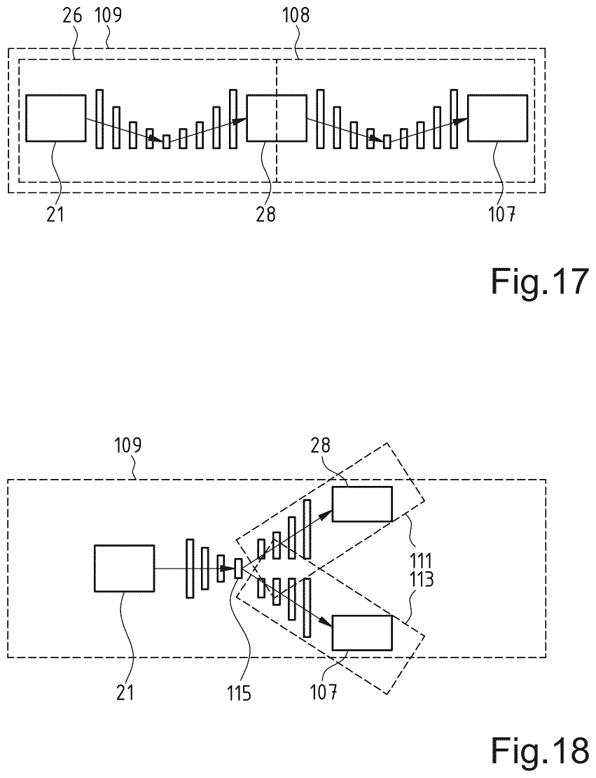

In a preferred example illustrated in FIGS. 17 and 18, the machine learning model 26 for reducing a noise level of an aerial image is trained jointly with a machine learning model 108 for defect detection in an aerial image 21 of a photolithography mask, wherein the training data comprises defect annotations, and wherein the loss function is a joint loss function that evaluates the prediction accuracy of the machine learning model 26 for reducing a noise level and of the machine learning model 108 for defect detection. Both parts of the loss function can be weighted.

A defect annotation may denote a data structure that describes the presence and characteristics of a defect within an image. A defect annotation may include, for instance, a defect category (e.g., crack, scratch, deformation), a spatial description of the defect such as a bounding box, polygon, or pixel mask, and optional metadata such as severity level or confidence values. Such defect annotations serve as structured inputs for training, validating, or evaluating automated defect-detection and classification systems.

As illustrated in FIG. 17, the joint machine learning model 109 can have a sequential structure by using the output of the machine learning model for reducing a noise level 26, the denoised aerial image 28, as input for the machine learning model for defect detection 108 that computes the final defect detection 107, e.g., a list of defect coordinates, a segmentation, a list of bounding boxes, etc. Due to the joint training, the denoised aerial image 28 is particularly well suited for defect detection.

Instead of subsequently applying a machine learning model for defect detection 108 after the machine learning model for reducing a noise level 26, a joint machine learning model 109 containing two heads—a denoising head 111 and a defect detection head 113 can be implemented. The denoising head 111 computes the denoised aerial image 28, and the defect detection head 113 computes the defect detection 107. The defect detection 107 is, thus, obtained by applying the machine learning model 108 for defect detection to the output of an intermediate layer 115 of the machine learning model 26 for reducing a noise level. In this way, intermediate feature maps before the final noise-reduction are used for defect detection. These may provide features that are better suited for defect detection than the final denoised image 28. In this way, the machine learning models share some of the layers at the beginning. After they branch, they process the information in different ways to obtain a denoised aerial image 28 and a defect detection 107.

A joint training means that a single joint machine learning model 109 is trained to perform both tasks, denoising and defect detection, simultaneously or subsequently. To accomplish this, the defect detection errors can be back-propagated not only into the machine learning model 108 for defect detection but also into the machine learning model 26 for reducing a noise level of an aerial image. In this way, the defect detection prediction accuracy is improved, since the denoised aerial images 28 are specifically adapted to allow for high quality defect detections. In case, the joint machine learning model 109 has a denoising head 111 and a defect detection head 113, in a training cycle the denoising head 111 and the defect detection head 113 can be trained alternatingly in order to adapt the weights to both tasks simultaneously. Alternatively, the heads can be trained subsequently.

Since both tasks are solved together, they can exploit information from each other yielding predictions of higher accuracy. For example, the machine learning model 26 for reducing a noise level of an aerial image 21 learns to denoise particularly well the aerial image regions that are crucial for an accurate defect prediction. At the same time, the machine learning model 108 for defect detection learns to adapt the defect detection 107 to denoised aerial images 28. Furthermore, annotations for the defect detection task become more reliable and precise, since humans can annotate denoised aerial images 28 with a higher accuracy.

Instead of jointly training the machine learning model 26 for reducing a noise level and the machine learning model 108 for defect detection, both models can be trained separately as well and can still be used in conjunction.

A computer implemented method 100 for training a machine learning model 26 for reducing a noise level of an aerial image 21 can be used to train a machine learning model 26 for reducing a noise level that is used in a method for detecting defects in an aerial image according to the first embodiment of the invention.

Inspection systems often use time-delay integration (TDI) for imaging of photolithography masks. Such inspection systems contain a TDI sensor to scan TDI swaths across the photolithography mask. Successive scanning of multiple TDI swaths is performed because the field of view of the inspection system, and thus the TDI swath width, is typically less than the width of the photolithography mask.

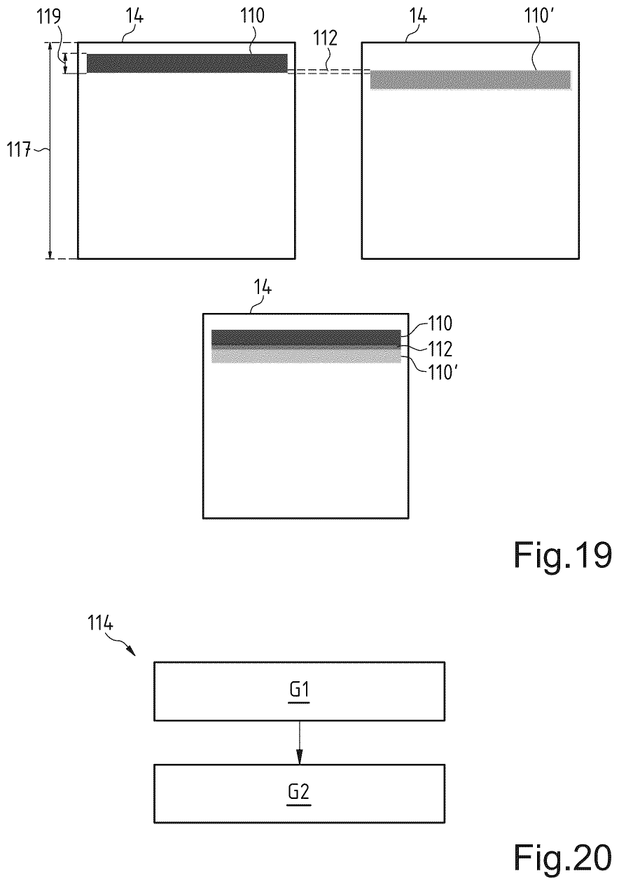

The process of scanning a photolithography mask 14 with an inspection tool to generate an aerial image 21 is illustrated in FIG. 19. The photolithography mask 14 is placed on a stage that can move in X and Y directions with high precision and accuracy. The stage is controlled by a computer that synchronizes its movement with the exposure of the light source. In one exposure, a beam of light is focused onto the photolithography mask by the illumination optics, and projective optics project the reflected or transmitted light from the surface of the mask to the TDI imaging sensor. As the stage moves, the signal from each pixel is shifted creating a series of images that are shifted by a certain number of pixels in the direction of motion. These images are then combined into a single image by adding the pixels values together and dividing by the number of exposures, resulting in a TDI swath 110 image. The swath image corresponds to a certain field of view of the inspection system on the photolithography mask. The width 119 of the swath 110, 110′ is less than the width 117 of the photolithography mask. The width 117 of the photolithography mask is measured in scan direction. The size of the swath image depends on the number of pixels in the TDI sensor and the length of the swath or mask width. Once a swath is acquired, the stage moves the photolithography mask 14 to the next position, where an image of a consecutive swath 110′ is captured. Consecutive swaths 110, 100′ contain an overlap area 112 that is used to align them. The overlap area 112 can contain markers to increase the alignment accuracy of images of consecutive swaths 110, 110′. The exposure and image acquisition process is repeated until the entire photolithography mask 14 is scanned. The images of consecutive swaths 110, 110′ are stitched together by a software algorithm that aligns the overlap area 112, thereby producing an aerial image 21 of the photolithography mask 14.

The overlap areas 112 of consecutive swaths 110, 110′ preferably contain markers. The markers are detected in images of consecutive swaths 110, 110′, and the images are aligned using the markers. To this end, registration methods can be used. The markers should be clearly and easily identifiable in an image. In this way, a more accurate alignment of images is possible. However, even without special markers in the overlap areas 112 images of consecutive swaths 110, 110′ can still be aligned based on the structures on the photolithography mask.

The overlap areas 112 of consecutive swaths 110, 100′ can be used to generate training data for a machine learning model 26 that is trained to reduce a noise level of an aerial image, since the overlap areas 112 contain two different noise realizations of the same area of the photolithography mask.

According to a fifth embodiment of the invention illustrated in FIG. 20, a method 114 for generating training data for training a machine learning model for reducing a noise level of an aerial image of a photolithography mask comprises: imaging the photolithography mask in swaths using an inspection system to obtain an aerial image of the photolithography mask, the swaths having a width less than the width of the photolithography mask and corresponding to a field of view of the inspection system, wherein consecutive swaths partially overlap in a step G1; and generating training data by obtaining pairs of source aerial images and corresponding target aerial images from images of overlap areas of consecutive swaths in a step G2.

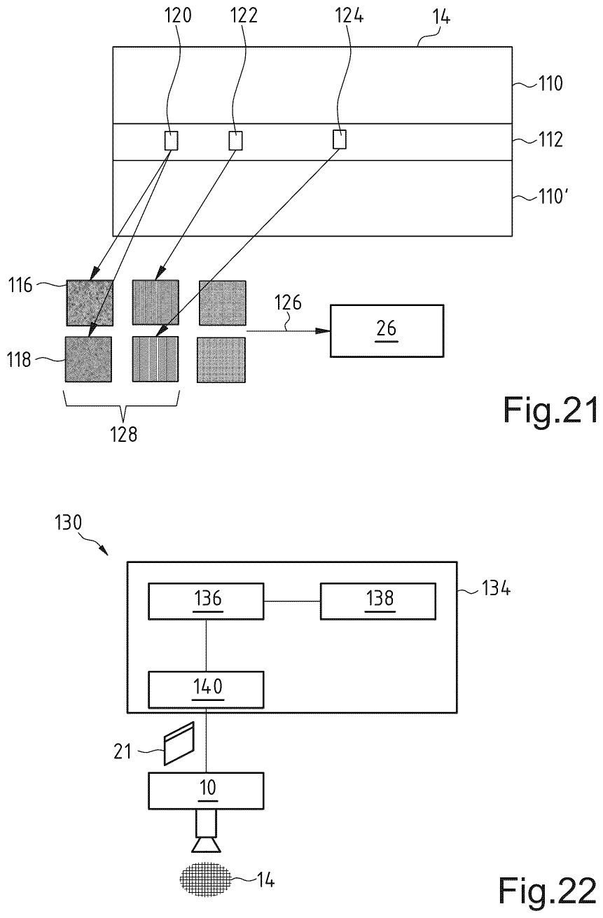

As illustrated in FIG. 21, source aerial images 116 and target aerial images 118 can be obtained from the overlap area 112 of consecutive swaths. For example, a source aerial image 116 can be obtained from a subsection 122 of the image of one of the swaths 110, 110′ within the overlap area 112, and a corresponding target aerial image can be obtained from a subsection 124 of the image of the other swath of consecutive swaths 110, 110′ within the overlap area 112, such that the subsection 124 shows the same or similar structures of the photolithography mask. In particular, a source aerial image 116 can be obtained from a subsection 120 of the image of one of the swaths 110, 110′ within the overlap area 112, and the corresponding target aerial image 118 can be obtained from the overlapping subsection 120 of the source aerial image 116 in the image of the other swath.

The source aerial image 116 and the target aerial image 118 show the same or similar structures of the photolithography mask but a different noise realization. For this reason, a target aerial image 118 corresponding to a source aerial image 116 can also be obtained by applying a function to a source aerial image and a subsection of the other swath of consecutive swaths 110, 110′ that shows the same or similar structures of the photolithography mask, for example an averaging function. This target aerial image 118 has a higher SNR than the source aerial image 116. By using target aerial images 118 of higher SNR, a higher prediction accuracy can be achieved.

In an example, a source aerial image 116 is obtained by selecting a subsection 120 of one of the swaths 110 within the overlap area 112 of consecutive swaths 110, 110′, and the corresponding target aerial image 118 is obtained by averaging the source aerial image 116 and the overlapping subsection 120 in the other swath of the consecutive swaths 110, 110′.

The source aerial images 116 and the target aerial images 118 can be used as training images to train a generative machine learning model for reducing a noise level. Due to the larger number of training images of the same location, a generative model such as a conditional generative adversarial neural network (GAN) or a diffusion model can be trained successfully. The large training dataset makes the trained generative model more stable with respect to variations in the input aerial images.

Further training images can be used to train the machine learning model for reducing a noise level of an aerial image, for example simulated aerial images. The further training images can, for example, be generated as described above with respect to the fourth embodiment of the invention. Noise free simulated target images 118 can, for example, be used to flatten the loss landscape or to guide the training towards a promising direction when training a diffusion based denoising algorithm.

The generated training data 128 can be used for training a machine learning model 26 for reducing a noise level of an aerial image 21, for example, using a computer implemented method 100 according to the fourth embodiment of the invention.

A system 130 for detecting defects 22 in a photolithography mask 14 according to an eighth embodiment of the invention is illustrated in FIG. 22. The system 130 comprises: an optical system 10, 10′ configured to provide an aerial image 21 of the photolithography mask 14; one or more processing devices 138; one or more machine-readable hardware storage devices 136 comprising instructions that are executable by one or more processing devices 138 to perform operations comprising any one of the methods for detecting defects in an aerial image 21 of a photolithography mask according to any one of the examples or aspects according to the first, second or third embodiment of the invention.

The optical system 10, 10′ provides the aerial image 21 to a data analysis device 134. The one or more processing devices 138 can be implemented, e.g., as a central processing unit (CPU), graphics processing unit (GPU) or tensor processing unit (TPU). The one or more processing devices 138 can receive the aerial image 21 via an interface 140. The one or more processing devices 138 can load program code from a memory, e.g., program code for executing a method for detecting defects 22 according to the second, third or fourth embodiment of the invention as described above. The one or more processing devices 138 can execute the program code.

In some implementations, after the defects 22 are found using the methods and systems described above, the photolithography mask can be modified to repair or eliminate the defects. Repairing the defects can include, e.g., depositing materials on the mask using a deposition process, or removing materials from the mask using an etching process.

In some implementations, the information about the defects serves as feedback to improve the process parameters of the mask manufacturing process. For example, after the defects are identified from a first photolithography mask or first batch of photolithography masks, the process parameters of the manufacturing process are adjusted accordingly to reduce defects in a second mask or a second batch of masks.

In some implementations, each of the one or more processing devices 138 can include one or more processor cores, and each processor core can include logic circuitry for processing data. For example, a processor can include an arithmetic and logic unit (ALU), a control unit, and various registers. Each processor can include cache memory. Each processor can include a system-on-chip (SoC) that includes multiple processor cores, random access memory, graphics processing units, one or more controllers, and one or more communication modules. Each processor can include millions or billions of transistors.

In some implementations, the data analysis device 134 can include one or more computers, each computer can include one or more data processors for processing data, one or more storage devices for storing data, and/or one or more computer programs including instructions that when executed by the one or more computers cause the one or more computers to carry out the processes. The data analysis device 134 can include one or more input devices, such as a keyboard, a mouse, a touchpad, and/or a voice command input module, and one or more output devices, such as a display, and/or an audio speaker.

In some implementations, the data analysis device 134 can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Reference throughout this specification to “an embodiment” or “an example” or “an aspect” means that a particular feature, structure or characteristic described in connection with the embodiment, example or aspect is included in at least one embodiment, example or aspect. Thus, appearances of the phrases “according to an embodiment”, “according to an example” or “according to an aspect” in various places throughout this specification are not necessarily all referring to the same embodiment, example or aspect, but may refer to different embodiments, examples, or aspects. Furthermore, the particular features or characteristics may be combined in any suitable manner, as would be apparent to one of ordinary skill in the art from this disclosure, in one or more embodiments.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

The invention can be described by the following clauses:
1. A method for denoising an aerial image 21 of a photolithography mask 14, the method comprising:
   Acquiring an aerial image 21 of the photolithography mask 14 using an optical system 10, 10′;
   Denoising the acquired aerial image 21 using a machine learning model 26 that is trained to reduce a noise level of an aerial image 21.
2. A method 24 for detecting defects 22 in a photolithography mask 14, the method comprising the following steps:
   Acquiring an aerial image 21 of the photolithography mask 14 using an optical system 10,10′;
   Denoising the acquired aerial image 21 using a machine learning model 26 that is trained to reduce a noise level of an aerial image 21;
   Detecting defects 22 in the photolithography mask 14 using the denoised aerial image 28.
3. The method of clause 1 or 2, wherein the acquired aerial image 21 comprises shot noise.
4. The method of any one of the preceding clauses, wherein the aerial image 21 of the photolithography mask 14 is acquired by the optical system 10, 10′ using light of an actinic wavelength.
5. The method of any one of the preceding clauses, wherein a design of the photolithography mask 14 is provided as an additional input to the machine learning model 26 for reducing a noise level of an aerial image 21.
6. The method of any one of the preceding clauses, wherein the trained machine learning model 26 for reducing a noise level of an aerial image 21 comprises a deep learning model with an encoder-decoder architecture.
7. The method of any one of the preceding clauses, wherein the trained machine learning model 26 for reducing a noise level of an aerial image 21 comprises a variational auto-encoder.
8. The method of any one of the preceding clauses, wherein the trained machine learning model 26 for reducing a noise level of an aerial image 21 comprises a diffusion model 44 that is trained to decrease a noise level in the aerial image 21 of the photolithography mask 14 in multiple diffusion steps.
9. The method of any one of the preceding clauses, further comprising verifying the reduction of the noise level of the denoised aerial image 28 using an image quality criterion.
10. The method of clause 9, wherein the image quality criterion comprises comparing an estimated noise level and/or a measurement of preserved structure in the denoised aerial image 28 and in the acquired aerial image 21.
11. The method of clause 9 or 10, wherein defects 22 are detected in the denoised aerial image 28 by comparing the denoised aerial image 28 to a reference image 40, and wherein the image quality criterion comprises comparing the denoised aerial image 28 and the acquired aerial image 21 to an estimated mean image of the acquired aerial image 21 and the reference image 40.
12. The method of any one of clauses 9 to 11, further comprising, upon not fulfilling the image quality criterion, using the acquired aerial image 21 for detecting defects 22.
13. The method of any one of clauses 9 to 12, further comprising repeating the steps of the method multiple times, and, upon not fulfilling the image quality criterion for a number of acquired aerial images 21, initiating a re-training of the machine learning model 26 for reducing a noise level of an aerial image 21.
14. The method of any one of the preceding clauses, further comprising:
   Providing a reference image 40 for the acquired aerial image 21 of the photolithography mask 14;
   Denoising the reference image 40 using the trained machine learning model 26 for reducing a noise level of an aerial image 21;
wherein detecting defects 22 comprises comparing the denoised aerial image 28 to the denoised reference image 42.
15. The method of any one of the preceding clauses, wherein detecting defects 22 comprises comparing the denoised aerial image 28 to a reference image 40.
16. The method of any one of the preceding clauses, wherein detecting defects 22 comprises applying a trained machine learning model 108 for defect detection to the denoised aerial image 28.
17. The method of any one of the preceding clauses, wherein a joint machine learning model 109 is used for reducing a noise level of an aerial image 21 and for detecting defects 22 in the denoised aerial image 28.
18. A computer implemented method 100 for training a machine learning model 26 for reducing a noise level of an aerial image 21 of a photolithography mask 14 obtained by an optical system 10, 10′, the method comprising:
   Providing training data comprising pairs of source aerial images 116 and corresponding target aerial images 118 configured for training the machine learning model 26 for reducing a noise level of an aerial image 21 of a photolithography mask 14 obtained by an optical system 10, 10′; and
   Training the machine learning model 26 for reducing a noise level of an aerial image 21 by minimizing a loss function using the training data.
19. The method of clause 18, wherein the loss function comprises the distance between a predicted denoised source aerial image 28, obtained by presenting a source aerial image 116 to the machine learning model 26 for reducing a noise level of an aerial image 21, and the corresponding target aerial image 118.
20. The method of clause 18 or 19, wherein the loss function comprises a distance measure in the frequency domain.
21. The method of clause 20, wherein the loss function comprises a distance measure of a target aerial image 118 and a predicted denoised source aerial image 28 in the frequency domain, wherein the predicted denoised source aerial image 28 is obtained by presenting the corresponding source aerial image 116 to the machine learning model 26 for reducing a noise level of an aerial image 21.
22. The method of clause 20 or 21, wherein the loss function comprises a regularization term that measures a phase shift between a source aerial image 116 and a predicted denoised source aerial image 28, wherein the predicted denoised source aerial image 28 is obtained by presenting the source aerial image 116 to the machine learning model 26 for reducing a noise level of an aerial image 21.
23. The method of any one of clauses 18 to 22, wherein the machine learning model 26 for reducing a noise level of an aerial image 21 comprises a deep learning model with an encoder-decoder architecture.
24. The method of any one of clauses 18 to 23, wherein at least some source aerial images 116 and corresponding target aerial images 118 are misaligned.
25. The method of any one of clauses 18 to 24, wherein the source aerial image 116 of at least some of the pairs contains noise and the corresponding target aerial image 118 is noise-free.
26. The method of any one of clauses 18 to 25, wherein the source aerial image 116 and the corresponding target aerial image 118 of at least some of the pairs contain noise of a different level.
27. The method of any one of clauses 18 to 26, wherein the target aerial image 118 of at least some of the pairs is obtained by processing the corresponding source aerial image 116.
28. The method of any one of clauses 18 to 27, wherein the target aerial image 118 and the source aerial image 116 of at least some of the pairs are obtained by subsampling an aerial image 21 containing noise in different ways.
29. The method of any one of clauses 18 to 28, wherein the machine learning model 26 for reducing a noise level of an aerial image 21 is trained jointly with a machine learning model 108 for defect detection in an aerial image 21 of a photolithography mask 14, wherein the training data comprises defect annotations, and wherein the loss function is a joint loss function that evaluates the prediction accuracy of the machine learning model 26 for reducing a noise level and of the machine learning model 108 for defect detection.
30. The method of clause 16 or 17, wherein the machine learning model 26 for reducing a noise level of an aerial image 21 and the machine learning model 108 for defect detection are trained jointly according to clause 28.
31. The method of any one of the preceding clauses, wherein the bit depth of the weights of a trained machine learning model 26, 108 is reduced after training.
32. A method 114 for generating training data 128 for training a machine learning model 26 for reducing a noise level of an aerial image 21 of a photolithography mask 14, the method comprising:
   Scanning the photolithography mask 14 in swaths 110, 110′ using an inspection system to obtain an aerial image 21 of the photolithography mask 14, the swaths 110, 110′ having a width 119 less than the width 117 of the photolithography mask 14 and corresponding to a field of view of the inspection system, wherein consecutive swaths 110, 110′ partially overlap;
   Generating training data 128 by obtaining pairs of source aerial images 116 and corresponding target aerial images 118 from images of overlap areas 112 of consecutive swaths 110, 110′.
33. The method of clause 32, wherein the photolithography mask 14 contains markers in the overlap areas 112, and wherein consecutive swaths 110, 110′ are aligned using the markers.
34. The method of clause 32 or 33, wherein a source aerial image 116 is obtained by selecting a subsection of an image of one of the swaths 110, 110′ within the overlap area 112 of consecutive swaths 110, 110′, and wherein the corresponding target aerial image 118 is obtained by selecting a subsection of the image of the other swath 110, 110′ that shows the same or similar structures of the photolithography mask 14 as the source aerial image 116.
35. The method of clause 34, wherein the corresponding target aerial image 118 is the subsection of the image of the other swath 110, 110′ of the consecutive swaths 110, 110′ that overlaps with the source aerial image 116.
36. The method of any one of clauses 32 to 35, wherein a source aerial image 116 is obtained by selecting a subsection of an image of one of the swaths 110, 110′ within the overlap area 112 of consecutive swaths 110, 110′, and wherein the corresponding target aerial image 118 is obtained by averaging the source aerial image 116 and the overlapping subsection of the image of the other swath 110, 110′ of the consecutive swaths 110, 110′.
37. The method of any one of clauses 18 to 31, wherein the machine learning model 26 for reducing a noise level of an aerial image 21 is trained using training data 128 generated according to a method of any one of clauses 32 to 36.
38. The method of any one of clauses 32 to 36, wherein the generated training data 128 is used for training a machine learning model 26 for reducing a noise level of an aerial image 21 of a photolithography mask 14 according to any one of clauses 18 to 31.
39. The method of any one of clauses 1 to 17, wherein the machine learning model 26 for reducing a noise level of an aerial image 21 is trained using a method for training a machine learning model 26 for reducing a noise level of an aerial image 21 according to any one of clauses 18 to 31 or 37.
40. The method of any one of clauses 18 to 31 or 37, wherein the trained machine learning model 26 for reducing a noise level of an aerial image 21 is used in a method 24 for detecting defects 22 in a photolithography mask according to any one of clauses 1 to 17.
41. A computer-readable medium, on which a computer program executable by a computing device is stored, the computer program comprising code for executing a computer implemented method 100 for training a machine learning model 26 for reducing a noise level of an aerial image 21 according to any one of clauses 18 to 31 or 37.
42. A computer program product comprising instructions which, when the program is executed by a computer, cause the computer to carry out a computer implemented method 100 for training a machine learning model 26 for reducing a noise level of an aerial image according to any one of clauses 18 to 31 or 37.
43. A system 130 for defect detection in a photolithography mask 14, the system 130 comprising:
   an optical system 10, 10′ configured to acquire an aerial image 21 of the photolithography mask 14;
   one or more processing devices 138;
   one or more machine-readable hardware storage devices 136 comprising instructions that are executable by one or more processing devices 138 to perform operations comprising any one of the methods of clauses 1 to 17.

In a general aspect, the invention relates to a method 24 for detecting defects 22 in a photolithography mask 14, the method comprising the following steps: acquiring an aerial image 21 of the photolithography mask 14 using an optical system 10,10′; denoising the acquired aerial image 21 using a machine learning model 26 that is trained to reduce a noise level of an aerial image 21; and detecting defects 22 in the photolithography mask 14 using the denoised aerial image 28. The invention also relates to a method for training a corresponding machine learning model, to a method for generating training data for a corresponding machine learning model and to a system for detecting defects in photolithography masks.

### REFERENCE NUMBER LIST

10, 10′ Optical system
12 Light source
14 Photolithography mask
16 Illumination optics
17 Projection optics
18 Wafer plane
19 Projection section
20 Image sensor
21 Aerial image
22 Defect
24 Method
26 Machine learning model for reducing a noise level
28 Denoised aerial image
30 Additional input
32 Bottleneck
34 Encoder
36 Decoder
38 Skip connection
40 Reference image
42 Denoised reference image
44 Diffusion model
46 Stochastic process step
48 Sample
50 Stochastic process
52 Reverse stochastic process
54 Reverse stochastic process step
56 Sequence
58 Noise-free aerial image
60 Generated denoised aerial image
62 Method
70 Method
71 Method
72 Noise-free reference image
74 Difference image
76 Difference of denoised aerial images
78 Difference of noise-free aerial images
82 Horizontal axis
84 Vertical axis
86 Method
88 Fulfilled
90 Not fulfilled
92 Original acquired aerial image
94 Collecting
96 Initiating
98 Using
100 Computer implemented method
102 Convolutional block
104 Convolution layer
106 Dilated convolution layer
107 Defect detection
108 Machine learning model for defect detection
109 Joint machine learning model
110, 110′ Swath
111 Denoising head
112 Overlap region
113 Defect detection head
114 Method
116 Source aerial image
118 Target aerial image
120 Overlapping subsection
122 Subsection
124 Subsection
126 Training
128 Training data
130 System
134 Data analysis device
136 Hardware storage device
138 Processing device
140 Interface

What is claimed is:

1. A method for detecting defects in a photolithography mask, the method comprising the following steps:
acquiring an aerial image of the photolithography mask using an optical system;
denoising the acquired aerial image using a machine learning model that is trained to reduce a noise level of an aerial image; and
detecting defects in the photolithography mask using the denoised aerial image.

2. The method of claim 1, wherein the acquired aerial image comprises shot noise.

3. The method of claim 1, wherein a design of the photolithography mask is provided as an additional input to the machine learning model for reducing a noise level of an aerial image.

4. The method of claim 1, wherein the trained machine learning model for reducing a noise level of an aerial image comprises a diffusion model that is trained to decrease a noise level in the aerial image of the photolithography mask in multiple diffusion steps.

5. The method of claim 1, further comprising verifying the reduction of the noise level of the denoised aerial image using an image quality criterion.

6. The method of claim 5, wherein the image quality criterion comprises comparing an estimated noise level and/or a measurement of preserved structure in the denoised aerial image and in the acquired aerial image.

7. The method of claim 5, wherein defects are detected in the denoised aerial image by comparing the denoised aerial image to a reference image, and wherein the image quality criterion comprises comparing the denoised aerial image and the acquired aerial image to an estimated mean image of the acquired aerial image and the reference image.

8. The method of claim 5, further comprising, upon not fulfilling the image quality criterion, using the acquired aerial image for detecting defects.

9. The method of claim 5, further comprising repeating the steps of the method multiple times, and, upon not fulfilling the image quality criterion for a number of acquired aerial images, initiating a re-training of the machine learning model for reducing a noise level of an aerial image.

10. The method of claim 1, further comprising:
providing a reference image for the acquired aerial image of the photolithography mask; and
denoising the reference image using the trained machine learning model for reducing a noise level of an aerial image;
wherein detecting defects comprises comparing the denoised aerial image to the denoised reference image.

11. The method of claim 1, wherein detecting defects comprises comparing the denoised aerial image to a reference image.

12. The method of claim 1, wherein detecting defects comprises applying a trained machine learning model for defect detection to the denoised aerial image.

13. The method of claim 1, wherein a trained joint machine learning model is used for reducing a noise level of an aerial image and for detecting defects in the denoised aerial image.

14. A computer implemented method for training a machine learning model for reducing a noise level of an aerial image of a photolithography mask obtained by an optical system according to claim 1, the method comprising:
providing training data comprising pairs of source aerial images and corresponding target aerial images configured for training the machine learning model for reducing a noise level of an aerial image of a photolithography mask obtained by an optical system; and
training the machine learning model for reducing a noise level of an aerial image by minimizing a loss function using the training data.

15. The method of claim 14, wherein the loss function comprises a distance measure in the frequency domain.

16. The method of claim 15, wherein the loss function comprises a distance measure of a target aerial image and a predicted denoised source aerial image in the frequency domain, wherein the predicted denoised source aerial image is obtained by presenting the corresponding source aerial image to the machine learning model for reducing a noise level of an aerial image.

17. The method of claim 15, wherein the loss function comprises a regularization term that measures a phase shift between a source aerial image and a predicted denoised source aerial image, wherein the predicted denoised source aerial image is obtained by presenting the source aerial image to the machine learning model for reducing a noise level of an aerial image.

18. The method of claim 14, wherein the source aerial image and the corresponding target aerial image of at least some of the pairs contain noise of a different level that is not zero.

19. The method of claim 14, wherein the target aerial image of at least some of the pairs is obtained by processing the corresponding source aerial image.

20. The method of claim 12, wherein the machine learning model for reducing a noise level of an aerial image and the machine learning model for defect detection are trained jointly, wherein the training data comprises defect annotations, and wherein the loss function is a joint loss function that evaluates the prediction accuracy of the machine learning model for reducing a noise level and of the machine learning model for defect detection

21. A method for generating training data for training a machine learning model for reducing a noise level of an aerial image of a photolithography mask according to claim 14, the method comprising:
scanning the photolithography mask in swaths using an inspection system to obtain an aerial image of the photolithography mask, the swaths having a width less than the width of the photolithography mask and corresponding to a field of view of the inspection system, wherein consecutive swaths partially overlap; and
generating training data by obtaining pairs of source aerial images and corresponding target aerial images from images of overlap areas of consecutive swaths.

22. The method of claim 21, wherein a source aerial image is obtained by selecting a subsection of an image of one of the swaths within the overlap area of consecutive swaths, and wherein the corresponding target aerial image is obtained by selecting a subsection of the image of the other swath that shows the same or similar structures of the photolithography mask as the source aerial image.

23. The method of claim 22, wherein the corresponding target aerial image is the subsection of the image of the other swath of the consecutive swaths that overlaps with the source aerial image.

24. The method of claim 21, wherein a source aerial image is obtained by selecting a subsection of an image of one of the swaths within the overlap area of consecutive swaths, and wherein the corresponding target aerial image is obtained by averaging the source aerial image and the overlapping subsection of the image of the other swath of the consecutive swaths.

25. The method of claim 14, wherein the machine learning model for reducing a noise level of an aerial image is trained using training data generated by a method comprising:
scanning the photolithography mask in swaths using an inspection system to obtain an aerial image of the photolithography mask, the swaths having a width less than the width of the photolithography mask and corresponding to a field of view of the inspection system, wherein consecutive swaths partially overlap; and
generating training data by obtaining pairs of source aerial images and corresponding target aerial images from images of overlap areas of consecutive swaths

26. The method of claim 21, wherein the generated training data is used for training a machine learning model for reducing a noise level of an aerial image of a photolithography mask 14 obtained by an optical system using a method comprising:
providing training data comprising pairs of source aerial images and corresponding target aerial images configured for training the machine learning model for reducing a noise level of an aerial image of a photolithography mask obtained by an optical system; and
training the machine learning model for reducing a noise level of an aerial image by minimizing a loss function using the generated training data.

27. The method of claim 1, wherein the machine learning model for reducing a noise level of an aerial image is trained using a method for training a machine learning model for reducing a noise level of an aerial image comprising:
providing training data comprising pairs of source aerial images and corresponding target aerial images configured for training the machine learning model for reducing a noise level of an aerial image of a photolithography mask obtained by an optical system; and
training the machine learning model for reducing a noise level of an aerial image by minimizing a loss function using the training data.

28. The method of claim 14, wherein the trained machine learning model for reducing a noise level of an aerial image is used in a method for detecting defects in a photolithography mask comprising:
acquiring an aerial image of the photolithography mask using an optical system;
denoising the acquired aerial image using a machine learning model that is trained to reduce a noise level of an aerial image; and
detecting defects in the photolithography mask using the denoised aerial image.

29. A computer-readable medium, on which a computer program executable by a computing device is stored, the computer program comprising code for executing a computer implemented method for training a machine learning model for reducing a noise level of an aerial image according to claim 14.

30. A computer program product comprising instructions which, when the program is executed by a computer, cause the computer to carry out a computer implemented for training a machine learning model for reducing a noise level of an aerial image according to claim 14.

31. A system for defect detection in a photolithography mask, the system comprising:
an optical system configured to acquire an aerial image of the photolithography mask;
one or more processing devices; and
one or more machine-readable hardware storage devices comprising instructions that are executable by one or more processing devices to perform operations comprising the method of claim 1.

32. The system of claim 31, wherein the system is configured to scan the photolithography mask in time-delay integration (TDI) swaths to generate the aerial image.
